(19) United States
(12) Patent Application Publication
(10) Pub. No.: US 2025/0208794 A1
(43) Pub. Date: Jun. 26, 2025

(54) RECORDING DEVICE, NON-VOLATILE STORAGE DEVICE, AND RECORDING METHOD

(71) Applicant: Panasonic Intellectual Property Management Co., Ltd., Osaka (JP)

(72) Inventor: Isao KATO, Osaka (JP)

(21) Appl. No.: 19/077,788

(22) Filed: Mar. 12, 2025

Related U.S. Application Data
(63) Continuation of application No. PCT/JP2023/032655, filed on Sep. 7, 2023.

(30) Foreign Application Priority Data
Sep. 16, 2022 (JP) 2022-148119

(51) Int. Cl. G06F 3/06

(52) U.S. Cl. CPC G06F 3/0679; G06F 3/0613; G06F 3/0659

(57) ABSTRACT

A recording device records data in a non-volatile storage device at a guaranteed minimum recording speed. The recording device includes an interface unit physically connected to the non-volatile storage device and having a transfer speed higher than the minimum recording speed. The interface unit is configured to transmit a control command to the non-volatile storage device, the control command including a data write command instructing data recording, a command instructing speed guarantee recording and a command instructing a shift to an optimal performance operation mode, and transmits the data write command instructing data recording after transmitting the command instructing the speed guarantee recording and the command instructing the shift to the optimal performance operation mode.

### BACKGROUND

### 1. Technical Field

The present disclosure relates to a recording device that records data in a non-volatile storage device, a non-volatile storage device, and a speed guarantee recording method in a non-volatile storage device.

### 2. Description of the Related Art

Patent Literature (PTL) 1 discloses a technique that makes it possible to request a memory card to perform data recording in which a minimum recording speed is guaranteed.

PTL 1 discloses a procedure of reading and writing data performed between a host device and a memory card.

In PTL 1, an interface conforms to the PCI Express standard, and a protocol for accessing a non-volatile memory conforms to the NVM Express standard (hereinafter, abbreviated as “NVMe standard”).

Specifically, an imaging device as the host device and the memory card are connected by a PCI Express interface (hereinafter, abbreviated as a “PCIe interface”), and a protocol of the NVMe standard is used for reading data from the memory card and writing data to the memory card.

PTL 1: Unexamined Japanese Patent Publication No. 2020-177413

### SUMMARY

An object of the present disclosure is to provide a technique for suppressing a temperature rise of a non-volatile storage device when data recording in which a minimum recording speed is guaranteed is performed in the non-volatile storage device.

A recording device of the present disclosure is a recording device that records data in a non-volatile storage device at a guaranteed minimum recording speed, the recording device including an interface unit physically connected to the non-volatile storage device and has a transfer speed higher than the minimum recording speed, in which the interface unit is configured to transmit a control command to the non-volatile storage device, a control command including a data write command instructing data recording, a command instructing speed guarantee recording and a command instructing a shift to an optimal performance operation mode, and transmits the data write command instructing data recording after transmitting the command instructing the speed guarantee recording and the command instructing the shift to the optimal performance operation mode.

A non-volatile storage device of the present disclosure is a non-volatile storage device that records data at a guaranteed minimum recording speed using a recording device, the non-volatile storage device including an interface unit physically connected to the recording device and having a transfer speed higher than the minimum recording speed, in which the interface unit is configured to receive, from the recording device, a data write command instructing data recording, and a control command including a command instructing speed guarantee recording, and a command instructing a shift to an optimal performance operation mode, and receives the data write command instructing data recording, after receiving the command instructing the speed guarantee recording and the command instructing the shift to the optimal performance operation mode.

Further, a recording method of the present disclosure is a recording method executed in a recording device that records data in a non-volatile storage device at a minimum recording speed via an interface unit having a transfer speed higher than a guaranteed minimum recording speed, the recording method including transmitting a command instructing speed guarantee recording and a command instructing a shift to an optimal performance operation mode, and transmitting a data write command instructing the data recording to the non-volatile storage device.

According to the present disclosure, it is possible to provide a technique for suppressing a temperature rise of a non-volatile storage device when data recording in which a minimum recording speed is guaranteed is performed in the non-volatile storage device.

### BRIEF DESCRIPTION OF THE DRAWINGS

FIG. 1 is a configuration diagram of a storage system according to the present disclosure.

FIG. 2 is a configuration diagram of the storage system according to the exemplary embodiment.

FIG. 3 is a configuration diagram of the storage system according to the exemplary embodiment.

FIG. 4 is a diagram illustrating an outline of a configuration of an input/output stage circuit of a full-duplex interface.

FIG. 5 is a diagram illustrating an outline of a configuration of an input/output stage circuit of a half-duplex interface.

FIG. 6 is a diagram illustrating a shape configuration example related to a terminal portion of an exemplary memory card.

FIG. 7 is a diagram illustrating a shape configuration example related to a terminal portion of an exemplary memory card.

FIG. 8 is a diagram illustrating a relationship between a video speed class and an interface speed mode in an SD memory card.

FIG. 9 is a diagram illustrating a relationship between a capacity and a card type in an SD memory card.

FIG. 10 is a diagram illustrating a relationship between a video speed class and a clock condition in an SD memory card.

FIG. 11 is a diagram illustrating a relationship between a video speed class and a data transfer speed in an SD memory card.

FIG. 12 is a diagram illustrating data transfer schemes of SDR and DDR.

FIG. 13 is a diagram illustrating a relationship between a transmission speed (bit rate) of a UHS-II interface and a clock frequency in an SD memory card.

FIG. 14 is a diagram illustrating a relationship between a bus speed mode and maximum power consumption of an SD memory card.

FIG. 15 is a diagram illustrating a relationship between a video speed class and power consumption limit of an SD memory card.

FIG. 16 is a diagram illustrating a correspondence relationship between a bus speed mode and an SD Express speed class of an SD Express card.

FIG. 17 is a diagram illustrating a data structure of “CMD20” of a conventional SD memory card.

FIG. 18 is a diagram illustrating an example of a control command formulated by the present inventor to transmit information instructing transition to an optimal performance operation mode from a recording device to a non-volatile storage device.

FIG. 19 is a diagram illustrating an example of a command sequence at the time of speed guarantee recording in a conventional SD memory card.

FIG. 20 is a diagram illustrating an example of a command sequence at the time of speed guarantee recording in the SD Express card.

FIG. 21 is a diagram illustrating an example of a command sequence for realizing transmission of information instructing transition to an optimal performance operation mode from the recording device to the non-volatile storage device in the SD memory card formulated by the present inventor.

FIG. 22 is a diagram illustrating an example of a command sequence for realizing transmission of information instructing transition to an optimal performance operation mode from the recording device to the non-volatile storage device in the SD Express card formulated by the present inventor.

FIG. 23 is a diagram illustrating that 8-bit DSPEC (stream ID), 4-bit “SCC” of “CMD20”, and 3-bit “CNT/ID” are described in DSPEC (16 bits) of the data-write command of the NVMe standard.

FIG. 24 is a diagram illustrating a specific example of parameters in a case where the function of “CMD 20” is allocated to a data write command according to the NVMe standard.

FIG. 25 is a diagram illustrating a data structure of a data set management command of the NVMe standard.

FIG. 26 is a diagram illustrating an example of assignment of the “CMD20” function by parameter setting of a data set management command of the NVMe standard.

FIG. 27 is a diagram illustrating a data structure of “CMD6” of a conventional SD memory card.

FIG. 28 is a diagram illustrating a data structure of a set features command of the NVMe standard.

FIG. 29 is a diagram illustrating a function (Feature) designated by a feature identifier of a set features command of the NVMe standard.

FIG. 30 is a diagram illustrating a data structure of a set features command for setting a power consumption management function of the NVMe standard.

FIG. 31 is a diagram illustrating an example of a plurality of Power States (power consumption states) supported by an SD Express card.

FIG. 32 is a diagram illustrating a structure of an identify controller data structure, a power state, and a vendor specific area of the NVMe standard.

FIG. 33 is a diagram illustrating an example of a Speed Class and a Speed Class Power State to be notified from an SD Express card to a host device.

FIG. 34 is a diagram illustrating an example of a Speed Class Power State of an SD Express card in a Gen4×1 card.

FIG. 35 is a diagram illustrating an example of a Speed Class Power State of an SD Express card in a Gen4×1 card.

FIG. 36 is a diagram illustrating an example of a command sequence for realizing transmission of information instructing transition to the optimal performance operation mode from the recording device to the non-volatile storage device in the SD Express card.

### DETAILED DESCRIPTIONS

Hereinafter, exemplary embodiments will be described in detail with reference to the drawings as appropriate. Note that unnecessarily detailed description is omitted in some cases. For example, detailed descriptions of already well-known matters and duplicated description of substantially identical configurations are not described in some cases. This is to avoid unnecessary redundancy of the following description and to facilitate understanding of those skilled in the art.

Note that the inventor provides the accompanying drawings and the following description in order for those skilled in the art to fully understand the present disclosure, and does not intend to limit the subject matter described in the claims by the accompanying drawings and the following description.

### 1. Configuration of Storage System

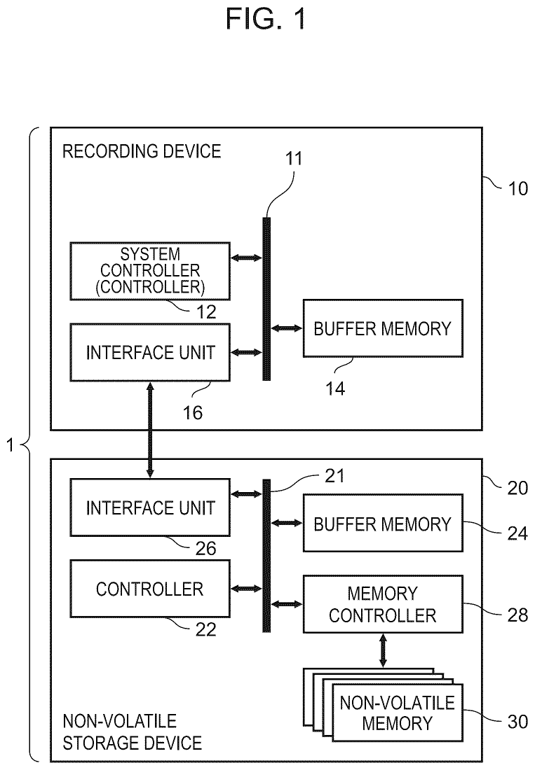

FIG. 1 illustrates a configuration of storage system 1 according to the present disclosure. Storage system 1 includes recording device 10 which is a host device and non-volatile storage device 20. In storage system 1, recording device 10 can write data in non-volatile storage device 20, and can read data stored in non-volatile storage device 20.

For example, storage system 1 including a PCIe/NVMe SSD as non-volatile storage device 20 and a PC as recording device 10 can be considered. The PCIe/NVMe SSD is a solid state drive (SSD) that adopts a PCI Express (PCIe) standard as a connection interface and adopts a Non-Volatile Memory Express (NVMe) standard as a data transfer protocol.

Another example is storage system 1 including an SD Express memory card as non-volatile storage device 20 and a moving image recording device such as a digital camera or a digital movie as recording device 10. The SD Express memory card is a memory card in which a PCIe interface is further added to an SD memory card having a conventional connection interface. The connection interface of the conventional SD memory card and the PCIe interface are exclusively used. That is, when the SD Express memory card is inserted into the SD memory card slot, the SD Express memory card operates as the SD memory card. On the other hand, when the SD Express memory card is attached to an SD Express-compatible device having a PCIe interface, the SD Express memory card is connected according to the PCIe standard, and transmits and receives data according to a protocol defined by the NVMe standard.

Recording device 10 includes system controller 12, buffer memory 14, and interface unit 16. These components are connected to each other by bus 11, and can transmit and receive data.

System controller 12 is a controller including a semiconductor integrated circuit. System controller 12 controls entire recording device 10. System controller 12 performs command issuance (transmission) control to non-volatile storage device 20 via interface unit 16, and controls a response from non-volatile storage device 20. In addition, system controller 12 prepares data to be written in non-volatile storage device 20, specifically, accumulates data to be written in non-volatile storage device 20 in buffer memory 14. System controller 12 processes data read from non-volatile storage device 20 and accumulated in buffer memory 14.

Buffer memory 14 temporarily accumulates data to be written in non-volatile storage device 20 and/or data read from non-volatile storage device 20.

Interface unit 16 communicates with interface unit 26 of non-volatile storage device 20. Specifically, interface unit 16 is a generic name of an interface that transmits and receives a command to non-volatile storage device 20, a response from non-volatile storage device 20, data to be written in non-volatile storage device 20, and/or data to be read from non-volatile storage device 20.

Non-volatile storage device 20 includes controller 22, buffer memory 24, interface unit 26, memory controller 28, and non-volatile memory 30. These components are connected to each other by bus 21, and can transmit and receive data.

Controller 22 controls the entire operation of non-volatile storage device 20. Buffer memory 24 is a memory that temporarily accumulates data received from recording device 10 and written in non-volatile memory 30 and/or data read from non-volatile memory 30 and transmitted to recording device 10.

Interface unit 26 communicates with interface unit 16 of recording device 10. Specifically, interface unit 26 receives a command from recording device 10 and transmits a response to recording device 10. In addition, interface unit 26 transmits and receives data to be written and/or read with interface unit 16 of recording device 10. Interface unit 26 is a generic term for interfaces capable of performing these operations.

Memory controller 28 is an integrated circuit that performs write control of data to non-volatile memory 30 and read control of data from non-volatile memory 30.

Non-volatile memory 30 is a non-volatile memory capable of holding data even when not energized, and is, for example, a flash memory.

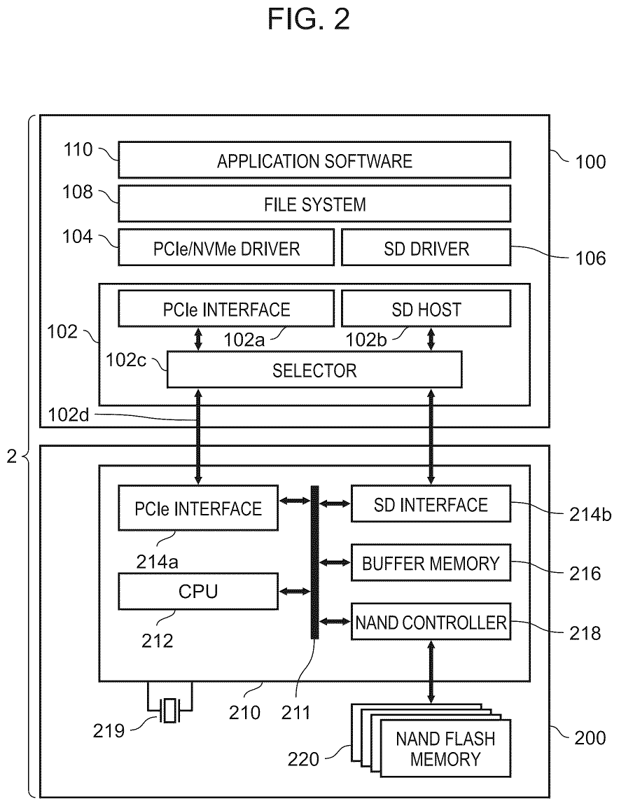

Next, a more specific configuration example of storage system 1 will be described with reference to FIG. 2.

FIG. 2 illustrates a configuration of storage system 2 according to the exemplary embodiment. Storage system 2 includes recording device 100 which is a host device and an SD Express memory card (hereinafter, abbreviated as “memory card 200”) which is a non-volatile storage device. Recording device 100 is, for example, a digital camera, a digital movie camera, or a drive recorder.

As described above, memory card 200 is configured by further adding the PCIe interface to the SD memory card having the connection interface according to the conventional SD standard. Memory card 200 supports a conventional SD interface and can be used in a conventional SD host device. Furthermore, in memory card 200, a PCIe interface is adopted in order to correspond to high-speed and large-capacity storage needs, and has a specification compatible with the PCI Express standard. A specific hardware configuration of memory card 200 will be described later.

Recording device 100 includes interface unit 102, PCIe/NVMe driver 104, SD driver 106, file system 108, and application software 110. Among these, PCIe/NVMe driver 104, SD driver 106, file system 108, and application software 110 function as a software layer of recording device 100.

Interface unit 102 corresponds to an interface portion in hardware of recording device 100, for example, a system on chip (SoC) which is a semiconductor product such as an LSI or a VLSI. Interface unit 102 includes PCIe interface 102a, SD host 102b, and selector 102c.

PCIe interface 102a is an interface for performing connection conforming to the PCIe standard. At the time of data transfer, PCIe interface 102a transmits and receives data using a protocol conforming to the NVMe standard.

SD host 102b is an interface for performing connection conforming to the SD standard. At the time of data transfer, SD host 102b transmits and receives data using a protocol conforming to the SD standard. Selector 102c is a switch that realizes exclusive use of PCIe interface 102a and SD host 102b.

Memory card 200 includes controller 210 and NAND flash memory 220.

Controller 210 includes CPU 212, PCIe interface 214a, SD interface 214b, buffer memory 216, and NAND controller 218.

CPU 212 corresponds to controller 22 in FIG. 1, and controls the entire operation of memory card 200.

PCIe interface 214a is an interface for performing connection conforming to the PCIe standard. At the time of data transfer, PCIe interface 214a transmits and receives data using a protocol conforming to the NVMe standard.

SD interface 214b is an interface for performing connection conforming to the SD standard. At the time of data transfer, SD interface 214b transmits and receives data using a protocol conforming to the SD standard.

Buffer memory 216 is a memory that temporarily accumulates data received from recording device 100 and written to NAND flash memory 220 and/or data read from NAND flash memory 220 and transmitted to recording device 100.

NAND controller 218 controls writing of data to NAND flash memory 220 and/or reading of data from NAND flash memory 220.

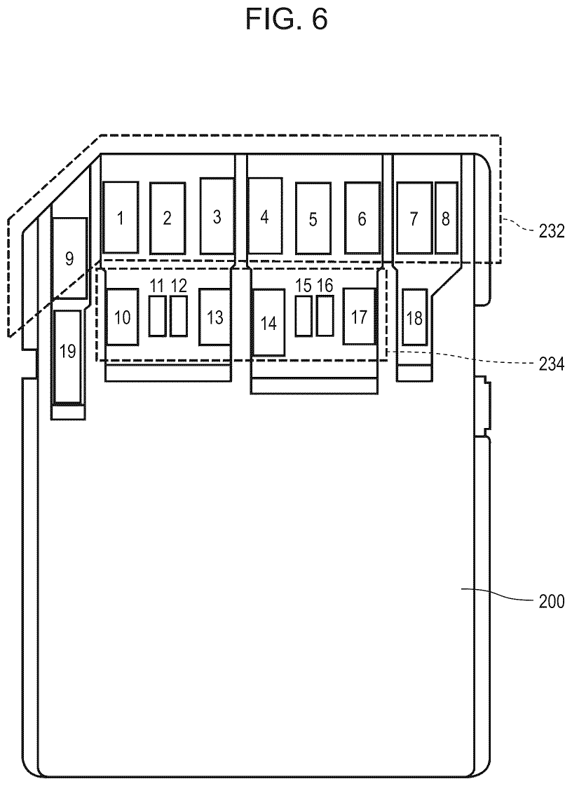

Next, specific shape configurations of PCIe interface 214a and SD interface 214b of memory card 200 will be described with reference to FIG. 6.

FIG. 6 illustrates a shape configuration example related to the terminal portion of exemplary memory card 200. Note that, in FIG. 6, the terminals of the respective interfaces are surrounded by a dotted line and illustrated as terminal group 232 and terminal group 234 for easy understanding.

Memory card 200 includes terminal group 232 (terminals “1” to “9”) which is a connection interface according to the SD standard, and terminal group 234 (terminals “10” to “17”) which is a connection interface according to the PCIe standard. The configuration example of FIG. 6 conforms to the SD Express card standard (SD Ver. 7.0).

When the specification of the UHS-II interface was formulated in the SD memory card standard (SD Ver. 4.0), terminal group 234 was newly provided for the UHS-II interface in addition to the terminal group for the SD interface (terminal group 232) defined in the standard before the SD Ver. 4.0.

Thereafter, when a specification for introducing a PCIe interface is formulated according to the SD Express card standard (SD Ver. 7.0), terminal group 234 newly provided for the UHS-II interface in the SD Ver. 4.0 is diverted as it is, and signals corresponding to one lane of the PCIe interface are allocated to terminal group 234.

In the SD Express card conforming to SD Ver. 7.0, since terminal group 234 of FIG. 6 is allocated to the PCIe interface, the UHS-II interface cannot be used.

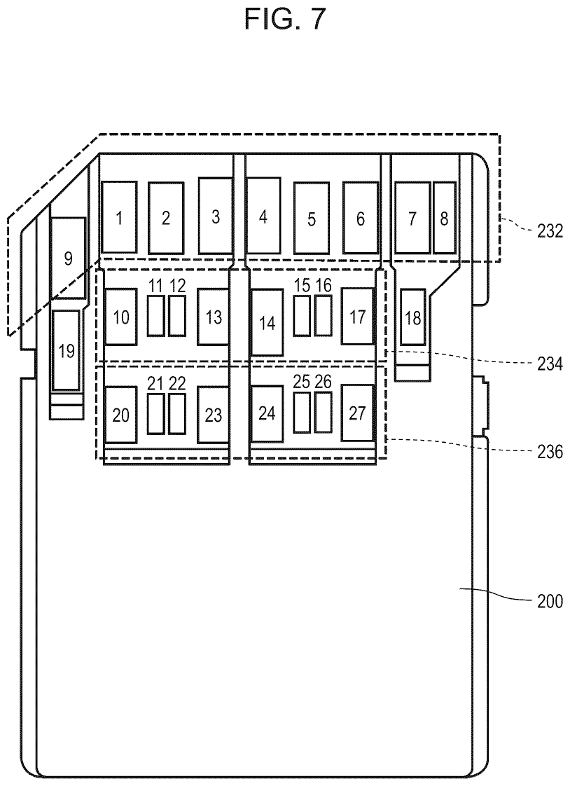

Further, in the SD Express card standard (SD Ver. 8.0), in order to allocate signals for 2 lanes of the PCIe interface, terminal group 236 is newly provided in addition to terminal group 232 and terminal group 234 as illustrated in FIG. 7.

The description of memory card 200 conforming to the SD Express card standard (SD Ver. 7.0) will be continued with reference to FIG. 6 again. The data bus of the SD interface includes four bits, and a bit “0” (DAT0) of the data line is allocated to a terminal “7”, a bit “1” (DAT1) is allocated to a terminal “8”, a bit “2” (DAT2) is allocated to a terminal “9”, and a bit “3” (DAT3) is allocated to a terminal “1”.

The data bus of the PCIe interface includes two sets of transmission paths by a differential transmission system, and a + signal of the Tx transmission path (host device output/card input) is allocated to the terminal “11”, a − signal of the Tx transmission path (host device output/card input) is allocated to the terminal “12”, a + signal of the Rx transmission path (host device input/card output) is allocated to the terminal “16”, and a − signal of the Rx transmission path (host device input/card output) is allocated to the terminal “15”. A pair (one set) of the Tx transmission path and the Rx transmission path is referred to as a lane in the PCIe standard, and memory card 200 illustrated in FIG. 6 includes a PCIe interface 1 lane.

Note that, in the SD Express card standard, in the PCIe interface, a transmission path for performing a command to a memory card, a response from the memory card, or writing and/or reading of data to and from the memory card is allocated to terminal group 234. However, four signals of a PCIe reset signal called PERST#, a PCIe clock request signal called CLKREQ#, and a PCIe differential clock signal pair called REFCLK+/REFCLK− are allocated to terminals “1”, “9”, “16”, and “15” of terminal group 232, respectively, and signals are switched and used at the time of operation on the SD interface and at the time of operation on the PCIe interface.

Next, specific shape configurations of PCIe interface 214a and SD interface 214b of memory card 200 conforming to the SD Express card standard (SD Ver. 8.0) will be described with reference to FIG. 7.

Similarly to FIG. 6, FIG. 7 illustrates a shape configuration example related to the terminal portion of exemplary memory card 200. Note that, in FIG. 7, the terminals of the respective interfaces are surrounded by dotted lines and illustrated as terminal group 232, terminal group 234, and terminal group 236 for easy understanding. Memory card 200 includes terminal group 232 (terminals “1” to “9”) which is a connection interface according to the SD standard, and terminal group 234 (terminals “10” to “17”) and terminal group 236 (terminals “20” to “27”) which are connection interfaces according to the PCIe standard.

A difference from the shape configuration of memory card 200 conforming to the SD Express card standard (SD Ver. 7.0) illustrated in FIG. 6 is that two lanes of a connection interface conforming to the PCIe standard are provided. The memory card 200 conforming to the SD Express card standard (SD Ver. 8.0) includes two sets (two lanes) of a pair (one set) of a Tx transmission path and an Rx transmission path, thereby achieving a transmission speed twice that of the SD Express card standard (SD Ver. 7.0).

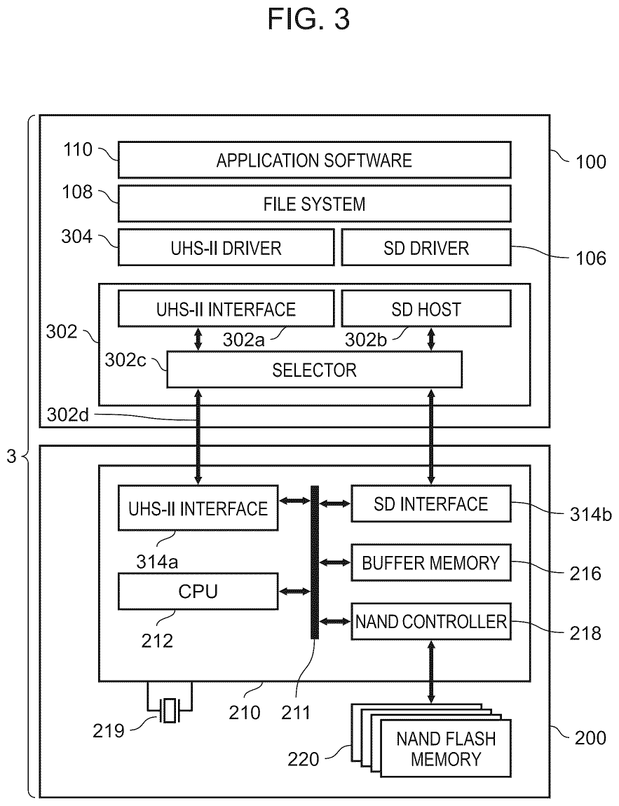

Next, another more specific configuration example of storage system 1 will be described with reference to FIG. 3.

FIG. 3 illustrates a configuration of storage system 3 according to the exemplary embodiment. Storage system 3 includes recording device 100 which is a host device and an SD memory card (hereinafter, abbreviated as “memory card 200”) which is a non-volatile storage device. Recording device 100 is, for example, a digital camera, a digital movie camera, or a drive recorder.

As described above, memory card 200 is configured by further adding the UHS-II interface defined by the SD memory card standard (SD Ver. 4.0) to the SD memory card having the connection interface according to the conventional SD standard. Memory card 200 supports a conventional SD interface and can be used in a conventional SD host device. Furthermore, in memory card 200, a UHS-II interface is adopted in order to correspond to high-speed and large-capacity storage needs. A specific hardware configuration of memory card 200 will be described later.

Recording device 100 includes interface unit 302, UHS-II driver 304, SD driver 106, file system 108, and application software 110. Among these, UHS-II driver 304, SD driver 106, file system 108, and application software 110 function as a software layer of recording device 100.

Interface unit 302 corresponds to an interface portion in hardware of recording device 100, for example, an SoC which is a semiconductor product such as LSI or VLSI. Interface unit 302 includes UHS-II interface 302a, SD host 302b, and selector 302c.

UHS-II interface 302a is an interface for performing connection conforming to UHS-II Addendum of the SD memory card standard. At the time of data transfer, UHS-II interface 302a transmits and receives data using a protocol conforming to UHS-II Addendum of the SD memory card standard.

SD host 302b is an interface for performing connection conforming to the SD standard. At the time of data transfer, SD host 302b transmits and receives data using a protocol conforming to the SD standard. Selector 302c is a switch that realizes exclusive use of UHS-II interface 302a and SD host 302b.

Memory card 200 includes controller 210 and NAND flash memory 220.

Controller 210 includes CPU 212, UHS-II interface 314a, SD interface 314b, buffer memory 216, and NAND controller 218.

CPU 212 corresponds to controller 22 in FIG. 1, and controls the entire operation of memory card 200. UHS-II interface 314a is an interface for performing connection conforming to UHS-II Addendum of the SD memory card standard. At the time of data transfer, UHS-II interface 314a transmits and receives data using a protocol conforming to UHS-II Addendum of the SD memory card standard.

SD interface 314b is an interface for performing connection conforming to the SD standard. At the time of data transfer, SD interface 314b transmits and receives data using a protocol conforming to the SD standard.

Buffer memory 216 is a memory that temporarily accumulates data received from recording device 100 and written to NAND flash memory 220 and/or data read from NAND flash memory 220 and transmitted to recording device 100.

NAND controller 218 controls writing of data to NAND flash memory 220 and/or reading of data from NAND flash memory 220.

Next, specific shape configurations of UHS-II interface 314a and SD interface 314b of memory card 200 will be described with reference to FIG. 6.

FIG. 6 illustrates a shape configuration example related to the terminal portion of exemplary memory card 200. Memory card 200 includes terminal group 232 (terminals “1” to “9”) which is a connection interface according to the SD standard, and terminal group 234 (terminals “10” to “17”) which is a connection interface according to UHS-II Addendum of the SD memory card standard. The configuration example of FIG. 6 conforms to the SD memory card standard (SD Ver. 4.0 or later).

The data bus of the SD interface includes four bits, and a bit “0” (DAT0) of the data line is allocated to a terminal “7”, a bit “1” (DAT1) is allocated to a terminal “8”, a bit “2” (DAT2) is allocated to a terminal “9”, and a bit “3” (DAT3) is allocated to a terminal “1”.

The data bus of the UHS-II interface includes two sets of transmission paths by a differential transmission system, and a + signal of the transmission path “0” is allocated to the terminal “11”, a − signal of the transmission path “0” is allocated to the terminal “12”, a + signal of the transmission path “1” is allocated to the terminal “16”, and a − signal of the transmission path “1” is allocated to the terminal “15”.

Note that, in the SD memory card standard, in the UHS-II interface, a transmission path for performing a command to the memory card, a response from the memory card, or writing and/or reading of data to and from the memory card is allocated to terminal group 234. However, two signals which are a UHS-II differential clock signal pair called RCLK+/RCLK− are allocated to the terminal “7” and the terminal “8” of terminal group 232, and the signals are switched and used at the time of operation on the SD interface and at the time of operation on the UHS-II interface.

When memory card 200 in FIG. 6 is an SD Express card, the maximum value of the transmission speed is 8 gigabits/sec. When memory card 200 is a UHS-II card, the maximum value of a transmission speed is about 3 gigabits/sec.

### 2. Speed Guarantee of SD Memory Card Standard

In the SD memory card standard, a specification related to a minimum recording speed guarantee (hereinafter, abbreviated as “speed guarantee”) is defined in order to prevent interruption of moving image recording due to fluctuation or decrease of a recording speed or occurrence of “frame dropping” in which one frame of a moving image is not recorded, for example, when moving image photographing and recording are performed.

The latest SD memory card speed guarantee specification is called a video speed class (VSC), and “VSC6” is a class that guarantees a minimum recording speed of 6 megabytes/sec, “VSC10” is a class that guarantees a minimum recording speed of 10 megabytes/sec, “VSC30” is a class that guarantees a minimum recording speed of 30 megabytes/sec, “VSC60” is a class that guarantees a minimum recording speed of 60 megabytes/sec, and “VSC90” is a class that guarantees a minimum recording speed of 90 megabytes/sec.

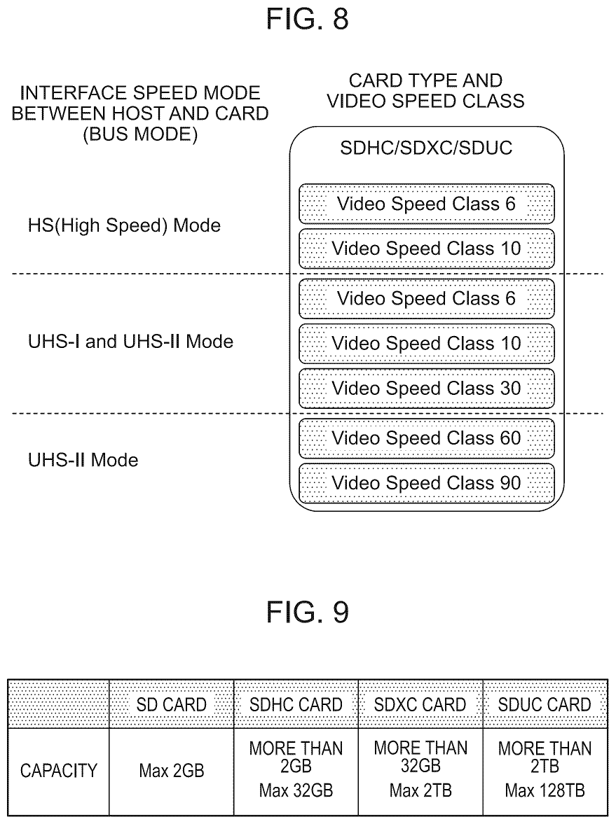

FIG. 8 illustrates the relationship between the interface speed mode between the host device (recording device 100) and the SD memory card and the video speed class, and the type of the SD memory card supporting the video speed class.

In the HS mode (High Speed Mode) of the SD interface, the VSC6 and the VSC10 are supported, that is, a minimum recording speed of up to 10 megabytes/sec (MB/s) can be guaranteed.

In the UHS-I mode of the SD interface, the VSC6, the VSC10, and the VSC30 are supported, that is, a minimum recording speed of up to 30 megabytes/sec (MB/s) can be guaranteed.

In addition, in the UHS-II mode by the UHS-II interface, the VSC6, the VSC10, the VSC30, the VSC60, and the VSC90 are supported, that is, a minimum recording speed of up to 90 megabytes/sec (MB/s) can be guaranteed.

Video speed classes are supported in an SDHC card, an SDXC card, and an SDUC card, as shown in a right side of FIG. 8, and the SD card is not covered.

FIG. 9 illustrates a relationship between the type of the SD memory card and the memory capacity. The SD card is supported by a card having a capacity of up to 2 gigabytes, the SDHC card is supported by a card having a capacity exceeding 2 gigabytes and up to 32 gigabytes, the SDXC card is supported by a card having a capacity exceeding 32 gigabytes and up to 2 terabytes, the SDUC card is supported by a card having a capacity exceeding 2 terabytes and up to 128 terabytes, and the video speed class is supported by a card having a capacity exceeding 2 gigabytes.

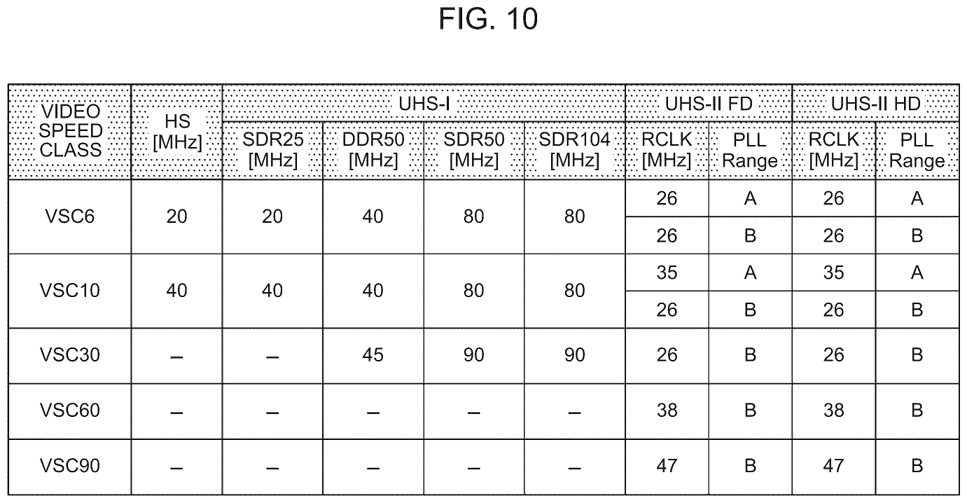

FIG. 10 is a table showing the clock conditions for measuring the speed of each video speed class.

For example, in the case of the VSC10, the guaranteed speed is measured when the clock frequency of the SD clock is 40 megahertz in the HS mode of the SD interface, the clock frequency of the SD clock is 40 megahertz in the UHS-I SDR25 mode of the SD interface and the DDR50 mode, and the clock frequency of the SD clock is 80 megahertz in the UHS-I SDR50 mode and the SDR104 mode of the SD interface.

Further, in the case of the VSC10, the guaranteed speed is measured when the reference clock (RCLK) is 35 megahertz in the PLL range A of the FD (Full Duplex) mode of the UHS-II interface, the reference clock is 26 megahertz in the PLL range B of the FD mode, the reference clock is 35 megahertz in the PLL range A of the HD (Half Duplex) mode, and the reference clock is 26 megahertz in the PLL range B of the HD mode.

In other words, the speed of each video speed class must be guaranteed under the conditions of the bus speed mode and clock condition (clock frequency) shown in FIG. 10.

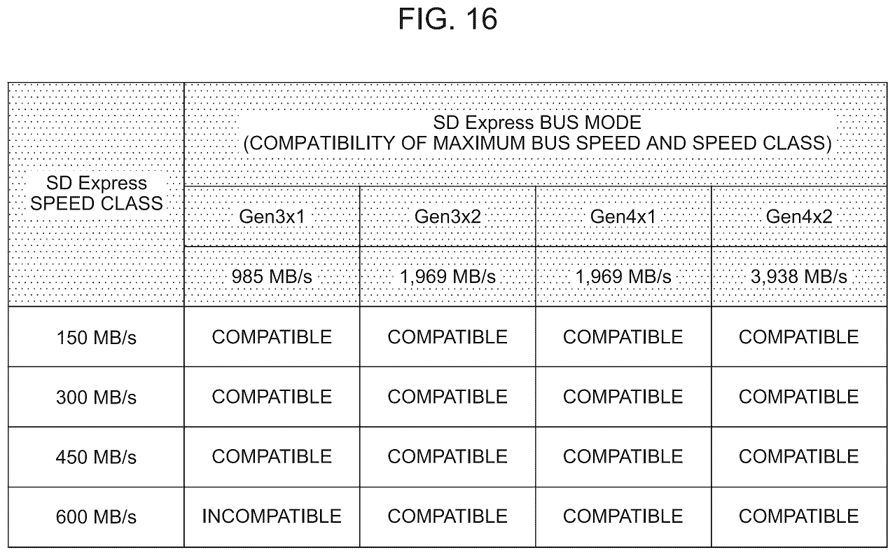

For the SD Express card, the speed guarantee specification is not formulated at present. However, in order to guarantee the recording speed of a 4K moving image (the number of pixels: 3,840×2,160) or an 8K moving image (the number of pixels: 7,680×4,320) with higher definition and high image quality in the future, it is considered that the specification of the video speed class faster than the conventional video speed class of 90 megabytes/sec such as 150 megabytes/sec, 300 megabytes/sec, 450 megabytes/sec, and 600 megabytes/sec illustrated in FIG. 16 is required.

### 3. Transmission System of PCIe

Here, a transmission system of the PCIe interface will be briefly described with reference to the drawings.

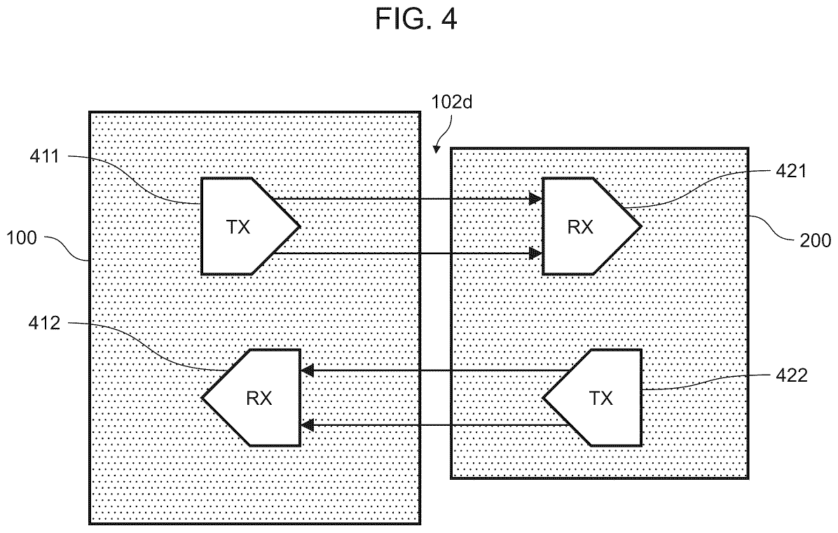

FIG. 4 is a configuration schematic diagram of an input/output stage circuit in a general FD interface of a differential transmission system, and is a diagram simply illustrated focusing on a transmission direction in order to facilitate understanding of characteristics of full-duplex communication.

Transmission circuit 411 of recording device 100 sends the command and/or the write data to the non-volatile memory from recording device 100 to memory card 200, and reception circuit 421 of memory card 200 receives the command and/or the write data to the non-volatile memory sent from recording device 100.

FIG. 4 illustrates that the transmission by the interface (transmission/reception function) including transmission circuit 411 of recording device 100 and reception circuit 421 of memory card 200 is the unidirectional transmission from recording device 100 to memory card 200.

Transmission circuit 422 of memory card 200 sends a response (completion) to the command and/or read data from the non-volatile memory from memory card 200 to recording device 100, and reception circuit 412 of recording device 100 receives the response (completion) to the command sent from memory card 200 and/or read data from the non-volatile memory.

FIG. 4 illustrates that the transmission by the interface (transmission/reception function) including transmission circuit 422 of memory card 200 and reception circuit 412 of recording device 100 is the unidirectional transmission from memory card 200 to recording device 100.

In the PCIe interface, an interface (transmission/reception function) configured by the transmission circuit and the reception circuit as described above is always oriented in one direction.

### 4. Transmission System of UHS-II

Next, the FD mode and the HD mode of the UHS-II interface will be briefly described with reference to the drawings.

The configuration outline of the input/output stage circuit in the FD mode of the UHS-II interface is illustrated in FIG. 4 and is the same as the transmission system of the PCIe interface described above, and thus the description thereof will be omitted.

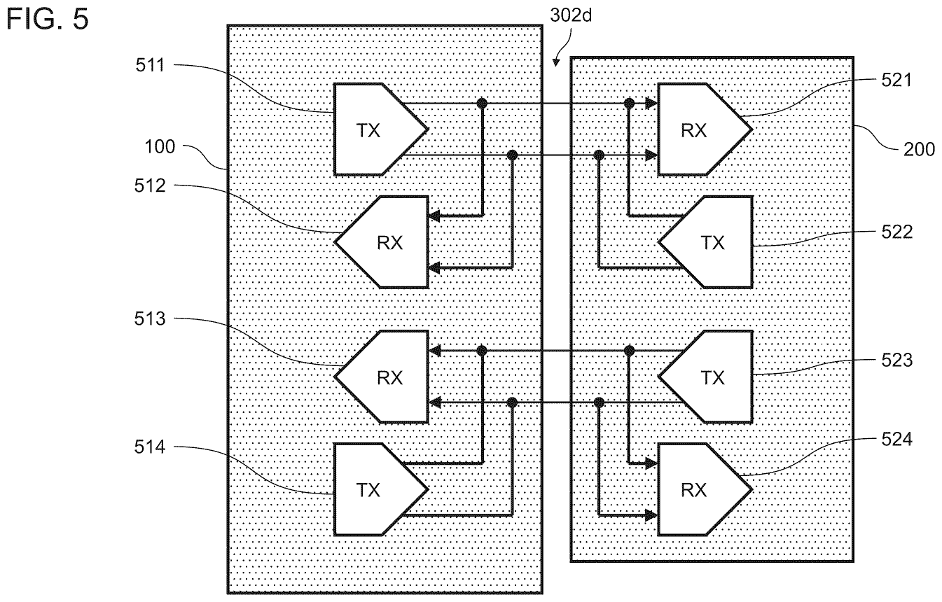

FIG. 5 is a configuration schematic diagram of an input/output stage circuit in a general HD interface of a differential transmission system, and is a diagram simply illustrated focusing on a transmission direction in order to facilitate understanding of features of half-duplex communication.

Transmission circuit 511 of recording device 100 sends the command and/or the write data to the non-volatile memory from recording device 100 to memory card 200, and reception circuit 521 of memory card 200 receives the command and/or the write data to the non-volatile memory sent from recording device 100.

Transmission circuit 523 of memory card 200 sends a response to the command and/or read data from the non-volatile memory from memory card 200 to recording device 100, and reception circuit 513 of recording device 100 receives the response to the command transmitted from memory card 200 and/or read data from the non-volatile memory.

Up to this point, the configuration and function are similar to those of the input/output stage circuit of FIG. 4 described above.

On the other hand, in the HD interface illustrated in FIG. 5, reception circuit 512 of recording device 100 is connected to transmission circuit 511 of recording device 100, and transmission circuit 522 of memory card 200 is connected to reception circuit 521 of the memory card.

In addition, reception circuit 524 of memory card 200 is connected to transmission circuit 523 of memory card 200, and transmission circuit 514 of recording device 100 is connected to reception circuit 513 of recording device 100.

Transmission circuit 511 and reception circuit 512 of recording device 100 operate exclusively, and reception circuit 521 and transmission circuit 522 of memory card 200 are also controlled to operate exclusively.

In addition, control is performed such that reception circuit 521 of memory card 200 is operated when transmission circuit 511 of recording device 100 is operated, and reception circuit 512 of recording device 100 is operated when transmission circuit 522 of memory card 200 is operated.

Similarly, transmission circuit 523 and reception circuit 524 of memory card 200 operate exclusively, and reception circuit 513 and transmission circuit 514 of recording device 100 are also controlled to operate exclusively.

In addition, control is performed such that reception circuit 513 of recording device 100 is operated when transmission circuit 523 of memory card 200 is operated, and reception circuit 524 of memory card 200 is operated when transmission circuit 514 of recording device 100 is operated.

With the above-described configuration and control illustrated in FIG. 5, it is possible to operate by switching the direction of the transmission path in the HD mode of the UHS-II interface.

Here, the SD memory card protocol of the SD memory card standard will be briefly described by exemplifying a case where data is written into the SD memory card.

When the host device (recording device 100) issues (transmits) the data write command to the SD memory card, a response to the data write command is returned (transmitted) from the SD memory card to the host device, and thereafter, the write data to the non-volatile memory is transmitted from the host device to the SD memory card according to the issued data write command.

The next command cannot be issued from the host device until the write data transmission by one data write command issued (transmitted) from the host device to the SD memory card is completed.

Therefore, in the FD communication according to the configuration of FIG. 4, during the write data transmission by the data write command, data transmission is not performed at all by the interface (transmission/reception function) including transmission circuit 422 of memory card 200 and reception circuit 412 of recording device 100.

On the other hand, in the HD communication configured as illustrated in FIG. 5, during the transmission of the write data by the data write command, in addition to the data transmission by the interface (transmission/reception function) including transmission circuit 511 of recording device 100 and reception circuit 521 of memory card 200, the data transmission by the interface (transmission/reception function) including transmission circuit 514 of recording device 100 and reception circuit 524 of memory card 200 can be simultaneously performed, and the transmission speed of the write data from recording device 100 to memory card 200 can be increased to about twice the FD communication configured as illustrated in FIG. 4.

As described above, in the UHS-II interface, two transmission systems of the FD mode transmission and the HD mode transmission are defined as specifications for determining the transmission speed.

Next, a PLL range A and a PLL range B, which are another specification for determining the transmission speed of the UHS-II interface, will be briefly described with reference to the drawings.

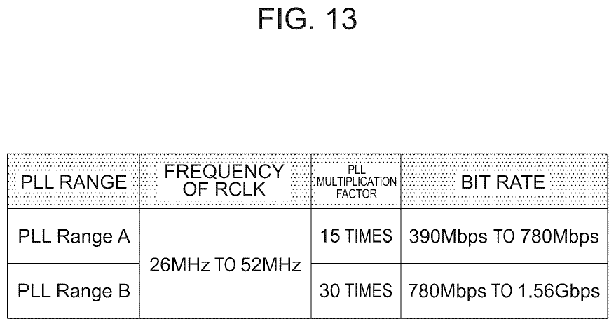

FIG. 13 illustrates a relationship between the PLL range of the UHS-II interface, the frequency of the reference clock (RCLK), the multiplication factor of the PLL, and the transmission speed (bit rate).

The frequency of the reference clock is variable, and the range thereof is 26 megahertz to 52 megahertz for both the PLL range A and the PLL range B.

On the other hand, the multiplication factors of the PLL are as follows: the PLL range A is 15 times, the PLL range B is 30 times, and the transmission speed (bit rate) is as follows: the PLL range A is 390 megabits/sec (=26 megahertz×15) to 780 megabits/sec (=52 megahertz×15), and the PLL range B is 780 megabits/sec (=26 megahertz×30) to 1.56 gigabits/sec (=52 megahertz×30).

### 5. Transmission system of UHS-I

The UHS-II interface employs a differential transmission system, and a UHS-II differential transmission signal is allocated to terminal group 234 illustrated in FIG. 6.

On the other hand, in the UHS-I, the same single-ended transmission system as that of the conventional SD interface is adopted, and the single-ended transmission signal of the UHS-I is allocated to terminal group 232 illustrated in FIG. 6.

Both the UHS-I and the conventional SD interface adopt the single-ended transmission system, but the signal voltage of the conventional SD interface is 3.3 V, whereas the signal voltage of the UHS-I is reduced to 1.8 V in order to increase the speed and reduce unnecessary radiation.

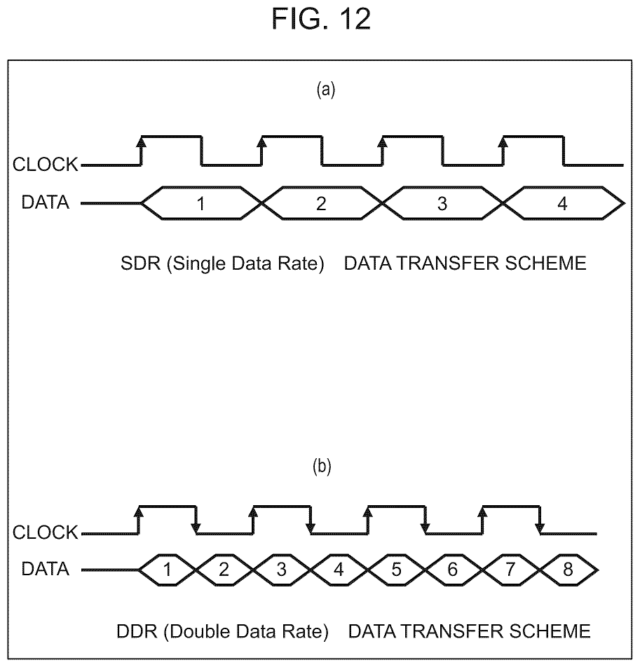

FIG. 12 is a diagram illustrating data transfer in the SDR mode and the DDR mode of the UHS-I.

In a single data rate (SDR) mode illustrated in FIG. 12(a), data is transferred at the timing of one edge of the clock, and in a double data rate (DDR) mode illustrated in FIG. 12(b), data is transferred at the timing of both edges of the clock. Therefore, if the clock frequencies are the same, data can be transferred at twice the speed of the SDR mode in the DDR mode.

### 6. Speed Guarantee Class of SD Memory Card Standard and Interface Data Transfer Speed

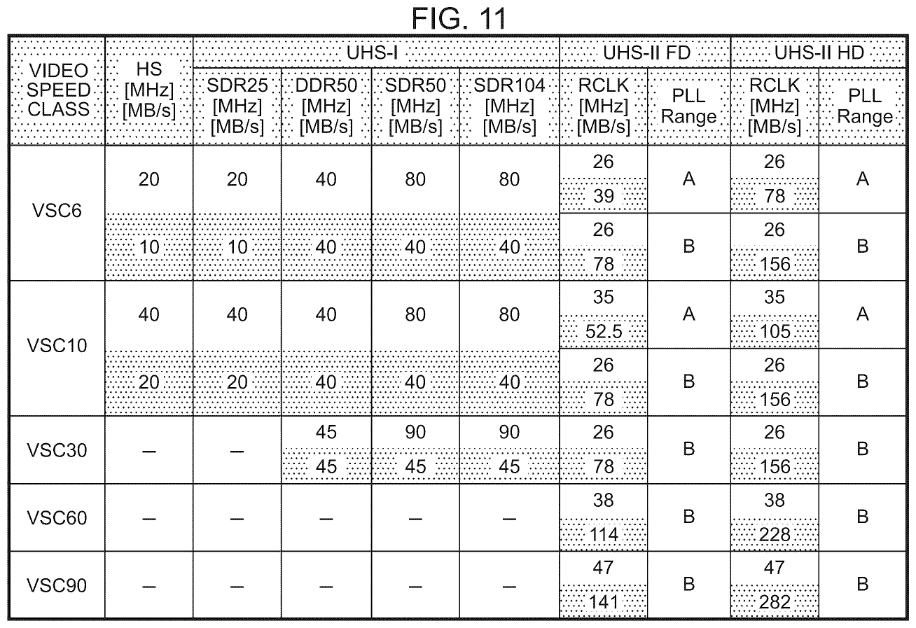

FIG. 11 is a diagram illustrating a relationship between the video speed class in the SD memory card and the data transfer speed of the interface derived from the UHS-II transmission system and the UHS-I transmission system described above and the clock condition of the video speed class illustrated in FIG. 10.

In the table in FIG. 11, an upper stage of each cell is the clock frequency shown in FIG. 10, a unit is megahertz, a lower stage of each cell is a data transfer speed of an interface, and a unit is megabyte/sec.

Hereinafter, the way of viewing the entire table of FIG. 11 will be presented by describing the data transfer speed of the interface calculated from the clock condition in the case of “VSC10” as an example.

Since the clock frequency of the SD clock is 40 megahertz in the HS mode of the SD interface, the transfer speed by the 4-bit bus of the SD interface is 20 megabytes/sec. Similarly, the transfer speed is 20 megabytes/sec also in the UHS-I SDR25 mode. Since the clock frequency of the SD clock is 40 megahertz in the UHS-I DDR50 mode and data transfer is performed by the DDR illustrated in FIG. 12, the transfer speed by the 4-bit bus is 40 megabytes/sec.

On the other hand, in the PLL range A of the UHS-II interface FD mode, since the frequency of the reference clock is 35 megahertz and the multiplication rate of the PLL is 15 times, the transmission speed is 525 megabits/sec in simple calculation. However, in the UHS-II interface, 8b10b encoding is adopted, and 8-bit data is converted (modulated) into 10bits and transmitted. Therefore, the substantial data transfer speed is 525 megabits/sec×(8/10)=420 megabits/sec. When this is converted into bytes/sec, the data transfer speed becomes 420 megabits/sec÷8 bits=52.5 megabytes/sec.

In addition, in the PLL range B of the UHS-II interface FD mode, since the frequency of the reference clock is 26 megahertz and the multiplication rate of the PLL is 30 times, the transmission speed is 780 megabits/sec in simple calculation. However, in the UHS-II interface, 8b10b encoding is adopted, and 8-bit data is converted (modulated) into 10 bits and transmitted. Therefore, the substantial data transfer speed is 780 megabits/sec×(8/10)=624 megabits/sec. When this is converted into bytes/sec, the data transfer speed becomes 624 megabits/sec÷8 bits=78 megabytes/sec.

For the UHS-II interface HD mode, as described in “4. Transmission system of UHS-II”, since the data transfer speed that is twice the data transfer speed of the UHS-II interface FD mode can be realized, the data transfer speed becomes 105 megabytes/sec in the PLL range A and 156 megabytes/sec in the PLL range B as illustrated in FIG. 11.

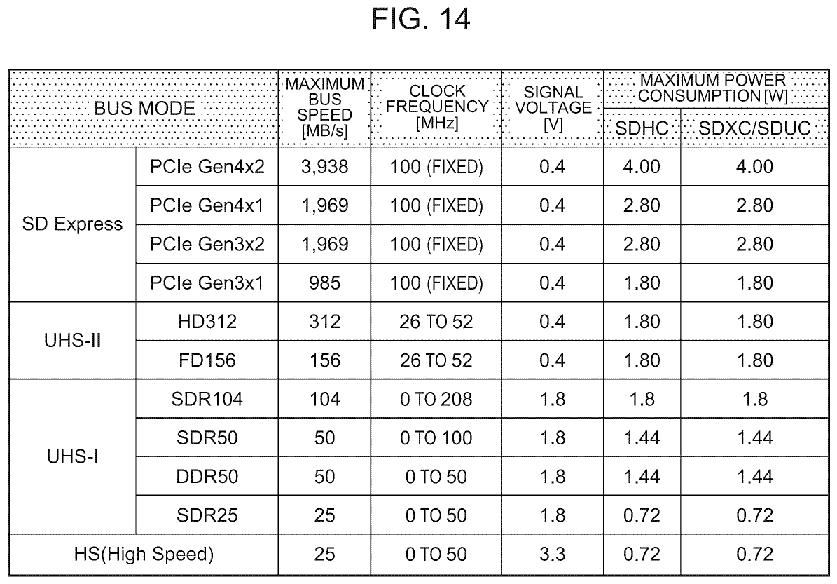

As described above, for example, while the recording speed guaranteed by the “VSC10” is 10 megabytes/sec, the maximum transfer speed of each bus speed mode of the interface (HS, UHS-I, UHS-II) conforming to the “VSC10” is 25 megabytes/sec to 312 megabytes/sec as illustrated in FIG. 14, which is faster than the minimum recording speed by more than necessary and sufficient, specifically, 2.5 times to 31 times.

### 7. Speed Guarantee Class, Power Consumption, and Thermal Problems of SD Memory Card Standard

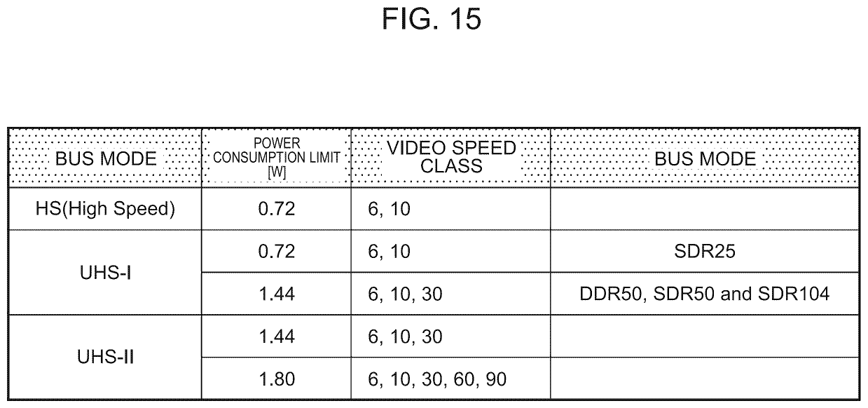

FIG. 14 illustrates a relationship between the bus speed mode and the maximum power consumption in the SD memory card standard, and FIG. 15 illustrates a relationship between the video speed class and the power consumption limit in the SD memory card standard.

FIG. 14 shows that the maximum power consumption increases as the bus speed increases, and FIG. 15 shows that the power consumption limit is relaxed, that is, larger power consumption is allowed as the guaranteed speed of the video speed class increases.

When the power consumption of the SD memory card increases, the amounts of heat generated by both recording device 100 in FIGS. 2 and 3 that supplies power to the SD memory card and memory card 200 in FIGS. 2 and 3 that consumes power increase.

With the increase in power consumption, the amounts of heat generated by recording device 100 and memory card 200 increase, and when the temperature of memory card 200 exceeds the operable temperature range, there is a possibility that interruption of moving image recording, “frame dropping” in which one frame of a moving image is not recorded, for example, occurs, and in the worst case, the controller constituting memory card 200 or the NAND flash memory is destroyed.

In the SD memory card standard, the operating temperature range of the SD memory card is set to −25° C. to 85° C.

In a case of a digital camera which is an example of a host device (recording device 100), when a still image is captured and image data thereof is recorded in an SD memory card, it is common to use the digital camera such that writing to the SD memory card does not occur for a while. Therefore, average power consumption per certain period unit of the host device and the SD memory card is lowered, and an extreme temperature rise of the host device and the SD memory card does not occur.

On the other hand, in a case where a moving image is continuously recorded while a recording speed is guaranteed by a digital movie camera as an example of a host device, a digital camera having a moving image photographing function, or the like, since writing to the SD memory card is continuously performed without interruption during moving image recording, average power consumption of the host device and the SD memory card per certain period unit increases, and when photographing takes a long time, temperatures of both of the host device and the SD memory card increase. As a result, an event greatly exceeding 85° C. which is the operable temperature range of the SD memory card has occurred, which is a problem.

A digital movie camera and a digital camera, which are examples of a host device, generate large heat by an imaging element such as a CMOS sensor and an image processing engine (SoC or the like which is a semiconductor product such as VLSI for performing image processing) due to the recent trend of high pixel and high image quality, but are mounted at a high density due to a demand for downsizing of a device. Therefore, heat dissipation is difficult, and thermal design is a major problem.

### 8. Implementation of Optimal Performance Action Instruction Method from Host Device to Memory Card

In view of the above background, there is a demand for a technique for keeping power consumption as low as possible when speed guarantee recording is performed.

Therefore, the present inventor has focused on the fact that, in the current standard of speed guarantee recording, when the guaranteed speed of the speed guarantee recording is significantly lower than the maximum bus speed of the memory card, that is, when there is a large margin in the performance of the maximum bus speed, there is no mechanism for operating the memory card with the speed reduced to the performance sufficient to achieve the guaranteed speed.

For example, in a case where memory card 200 conforming to the VSC90 (video speed class 90) is attached to recording device 100 of FIG. 3 and speed guarantee recording up to 90 megabytes/sec (MB/s) is performed, when the host device selects (sets) the HD mode of the UHS-II interface and the PLL range B, UHS-II interface 314a of memory card 200 operates at a maximum of 312 megabytes/sec as illustrated in bus speed mode “UHS-II HD 312” of FIG. 14, and in accordance with this, a clock of a high frequency is supplied to CPU 212, buffer memory 216, NAND controller 218, and NAND flash memory 220 so that the UHS-II interface operates at a performance corresponding to a speed of a maximum of 312 megabytes/sec, and the processing capacity is increased.

On the other hand, recording device 100 records data only at a speed of 90 megabytes/sec (MB/s) at the maximum. That is, there is a large difference of about 3.5 times between the maximum bus speed and the guaranteed speed of the speed guarantee recording.

Further, according to the bus speed mode and the clock condition of the VSC90 (video speed class 90) illustrated in FIGS. 10 and 11, it is possible to perform speed guarantee recording of 90 megabytes/sec (MB/s) at the speed of UHS-II interface 314a (141 megabytes/sec) when the FD mode and the PLL range B of the UHS-II interface are selected (set) and the RCLK supplied to memory card 200 by recording device 100 is set to 47 megahertz. That is, speed guarantee recording of 90 megabytes/sec (MB/s) can be performed at 141 megabytes/sec which is half or less of 312 megabytes/sec, and the operation at the maximum processing capacity by the clock supply of the high frequency to CPU 212, buffer memory 216, NAND controller 218, and NAND flash memory 220 for operating at the performance corresponding to the speed of 312 megabytes/sec is obviously excessive performance (overspecification).

In addition, in a case where the SD Express card (memory card 200) conforming to the SD Express speed class 600 MB/s illustrated in FIG. 16 is attached to recording device 100 of FIG. 2 and the speed guarantee recording up to 600 megabytes/sec (MB/s) is performed, when the host device performs the recording using Gen4 (fourth generation)×2 lanes of the PCIe interface, PCIe interface 214a of the SD Express card (memory card 200) operates at 3,938 megabytes/sec as illustrated in bus speed mode “Gen4×2” of FIGS. 14 and 16, and in accordance with this, a clock of a high frequency is supplied to CPU 212, buffer memory 216, NAND controller 218, and NAND flash memory 220 so as to operate at a performance corresponding to a speed of up to 3,938 megabytes/sec, and the processing capacity is increased to the maximum.

On the other hand, recording device 100 records data only at a speed of 600 megabytes/sec (MB/s) at the maximum. That is, there is a very large difference of about 6.6 times between the maximum bus speed and the guaranteed speed of the speed guarantee recording.

In order to solve the above problems, the present inventor has studied a technique in which a memory card is operated with minimum performance necessary for executing speed guarantee recording and power consumption of the memory card is suppressed by newly providing a unit for notifying a memory card of information instructing a shift to an optimal performance operation mode from a host device.

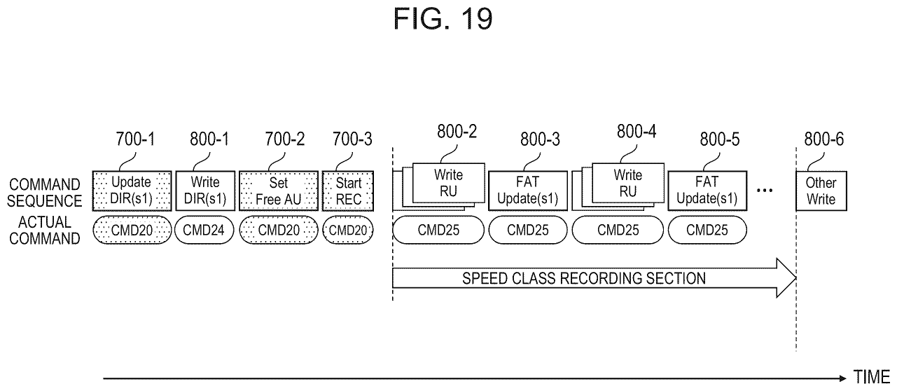

First, speed guarantee recording realized by the current SD memory card will be described with reference to FIG. 19.

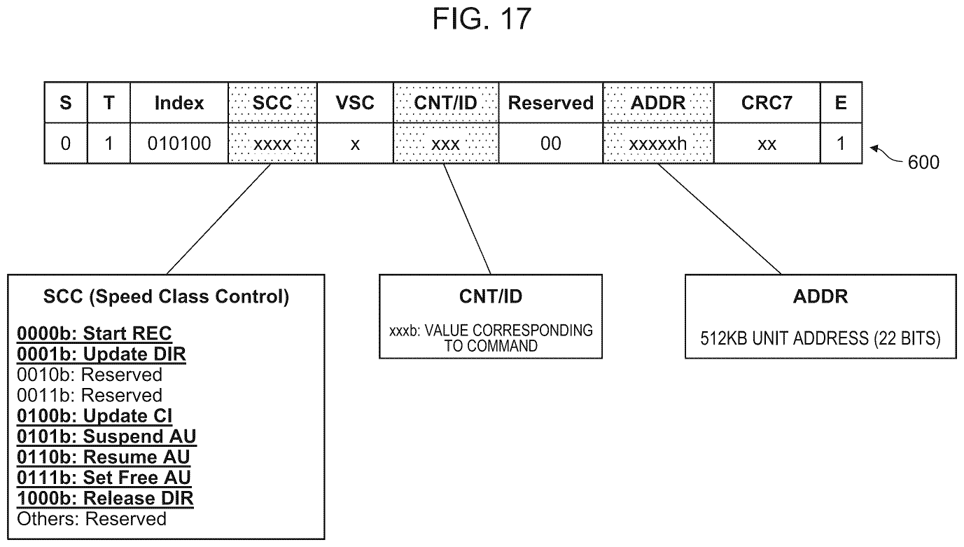

FIG. 19 illustrates an example of a command sequence at the time of speed guarantee recording in the SD memory card. In FIG. 19, a horizontal axis represents time, and recording device 100 issues a command to memory card 200 in order from a left side to a right side of the drawing. In the example shown in FIG. 19, the command is described as “CMD”, and is transmitted from the host device to the SD memory card. “CMD20” is a control command issued when the speed guarantee recording is performed in the SD memory card. FIG. 17 illustrates data structure 600 of “CMD20”. The speed guarantee recording is realized by parameters designated by “speed class control (SCC)”, “CNT/ID”, and “ADDR” in “CMD20”.

For example, first “CMD20” 700-1 notifies the SD memory card of the position of the directory entry of the data stream to be written from the host device (“SCC”=0001b in FIG. 17). In the directory entry, a file name, an attribute, and the like of a data stream to be written are recorded. Thereafter, “CMD24” 800-1 is issued, and writing (recording) to the directory entry is performed.

Note that “CMD24” of the SD memory card standard is a command for performing data writing of a single block (1 block=512 bytes).

Next, the position of allocation unit (AU) for performing the speed guarantee recording is designated from the host device to the SD memory card by “CMD20” 700-2 (“SCC”=0111b in FIG. 17).

At the time of speed guarantee recording, it is defined in the SD memory card standard that the data stream is written for each vacant allocation unit (vacant AU). At this time, the number of vacant allocation units (vacant AUs) that can be consecutively secured is designated in the “CNT/ID” field (FIG. 17). The maximum value of the number that can be designated is 8, and the “CNT/ID” field is 3 bits long.

Thereafter, “CMD20” 700-3 instructs the SD memory card from the host device to start the speed guarantee recording (“SCC”=0000b in FIG. 17).

Thereafter, speed guarantee recording represented as “speed class recording section” in FIG. 19 is performed. In the speed class recording section, “CMD25” 800-2 and 800-4, which are data write commands, are issued from the host device to the SD memory card, and speed guarantee data to be written, such as the photographed moving image data, is transmitted.

Note that “CMD25” of the SD memory card standard is a command for performing data writing of multiple blocks (n blocks=512×n bytes).

During continuous writing of the speed guarantee data to be written such as the photographed moving image data into the SD memory card, file system 108 of the host device shown in FIGS. 2 and 3 writes the appropriately updated FAT (file allocation table) according to the data in which the writing to the file has been completed into the SD memory card by issuing “CMD25” 800-3 and 800-5.

The “speed class recording section” ends when another write command (800-6) is issued.

The present inventor has considered that, in the sequence of a series of speed guarantee recording described above, at least before the speed guarantee recording is instructed, that is, before “CMD25” 800-2 (Write RU) in FIG. 19 is issued, the information instructing the shift to the optimal performance operation mode is notified to the SD memory card, so that the SD memory card can operate with the minimum performance necessary for executing the speed guarantee recording, and the power consumption of the memory card can be kept low.

Various specific means such as a method of using an unused (Reserved) argument of an existing command (CMD) defined in the SD memory card standard or a method of newly defining an undefined command in the SD memory card standard can be considered as means by which the host device notifies the SD memory card of the information instructing the shift to the optimal performance operation mode.

The exemplary embodiment of the present invention discloses, as an example, a method of using an unused code (value) of an argument of existing “CMD20” defined in the SD memory card standard.

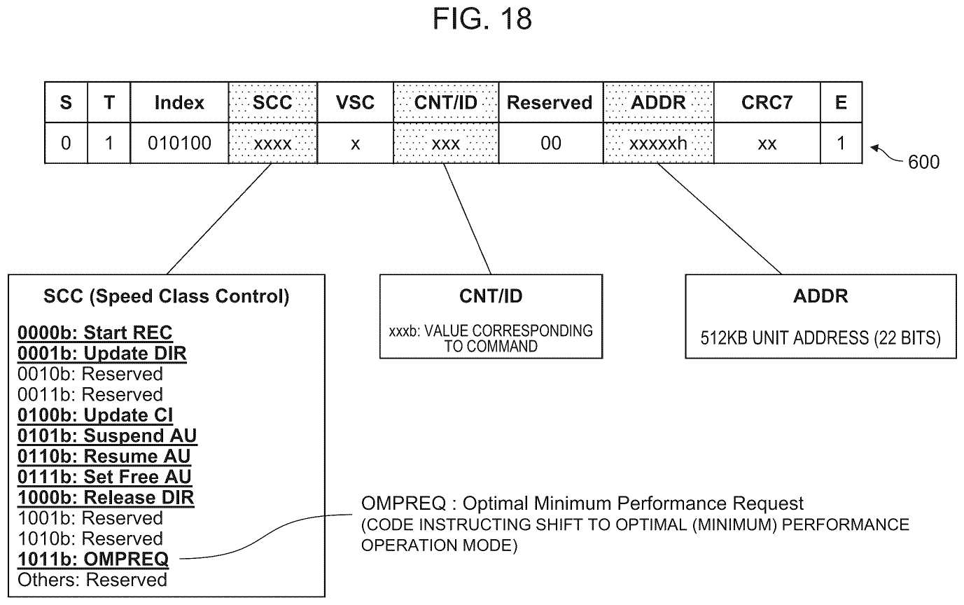

FIG. 18 illustrates an example in which the host device allocates information “OMPREQ” (Optimal Minimum Performance Request) instructing to shift to the optimal performance operation mode to an SD memory card, to “SCC”=1011b which is an unused code (value) of “speed class control (SCC)” which is an argument of existing “CMD20” defined in the SD memory card standard.

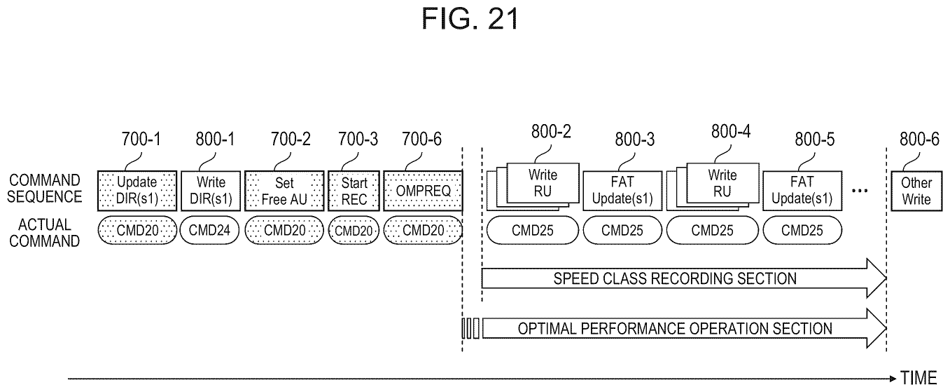

Next, an example in which the host device notifies the SD memory card of information instructing the shift to the optimal performance operation mode and then executes the speed guarantee recording will be described with reference to FIG. 21.

FIG. 21 illustrates an example of a command sequence in a case where the host device notifies (presents) the SD memory card of the information instructing the shift to the optimal performance operation mode and then executes the speed guarantee recording.

In the example shown in FIG. 21, the command is described as “CMD”, and is transmitted from the host device to the SD memory card.

“CMD20” is a control command issued when the speed guarantee recording is performed in the SD memory card.

FIG. 18 illustrates data structure 600 of “CMD20”. The speed guarantee recording is realized by parameters designated by “speed class control (SCC)”, “CNT/ID”, and “ADDR” in “CMD20”.

Referring again to FIG. 21. For example, first “CMD20” 700-1 notifies the SD memory card of the position of the directory entry of the data stream to be written from the host device (“SCC”=0001b in FIG. 18). In the directory entry, a file name, an attribute, and the like of a data stream to be written are recorded. Thereafter, “CMD24” 800-1 is issued and writing to the directory entry is performed.

Note that “CMD24” of the SD memory card standard is a command for performing data writing of a single block (1 block=512 bytes).

Next, the position of allocation unit (AU) for performing the speed guarantee recording is designated from the host device to the SD memory card by “CMD20” 700-2 (“SCC”=0111b in FIG. 18).

At the time of speed guarantee recording, it is defined in the SD memory card standard that the data stream is written for each vacant allocation unit (vacant AU). At this time, the number of vacant allocation units (vacant AUs) that can be consecutively secured is designated in the “CNT/ID” field (FIG. 18). The maximum value of the number that can be designated is 8, and the “CNT/ID” field is 3 bits long.

Thereafter, “CMD20” 700-3 instructs the SD memory card from the host device to start the speed guarantee recording (“SCC”=0000b in FIG. 18).

Next, an instruction to shift to the optimal performance operation mode is notified to the SD memory card by “CMD20” 700-6.

Upon receipt of “CMD20” 700-6 and the SD memory card recognizing the instruction to shift to the optimal performance operation mode, the SD memory card operates with the minimum performance required to execute the speed guarantee recording and shifts to an operation mode in which the power consumption of the memory card, represented as the “optimal performance operation section”, is kept low.

Here, in the non-volatile storage device including the SD memory card on which the NAND flash memory is mounted, in general, the total power consumption of CPU 212, buffer memory 216, and NAND controller 218 inside controller 210 illustrated in FIGS. 2 and 3 and the power consumption of NAND flash memory 220 are much larger than the power consumption of PCIe interface 214a, 214b, 314a, or 314b with the host device illustrated in FIGS. 2 and 3.

For example, in one circuit implementation example of UHS-II interface 314a of FIG. 3, there is a semiconductor power simulation result report in which the power consumption is 60 mW. On the other hand, as illustrated in FIG. 14, the maximum power consumption of the SD memory card provided with the UHS-II interface is 1.80 W, which is about 30 times the power consumption of UHS-II interface 314a.

These circuit blocks in controller 210 and the NAND flash memory normally operate with a clock multiplied and/or divided based on the clock generated (transmitted) by oscillator 219 illustrated in FIGS. 2 and 3.

In order to suppress power consumption as low as possible in a case where a command from a host device is not issued for a certain period of time or the like, controller 210 generally includes a mechanism for shifting to a power saving mode by decreasing a clock frequency by dividing a clock supplied to a circuit block inside controller 210 or the like.

Therefore, it is conceivable to perform power saving control in which the clock supplied to the circuit block inside controller 210 is set to the maximum clock frequency and operated before receiving “CMD20” 700-6 (OMPREQ), and the clock is set to the minimum clock frequency necessary for executing the speed guarantee recording and operated in the “optimal performance operation section” after receiving “CMD20” 700-6.

Thereafter, speed guarantee recording represented as “speed class recording section” in FIG. 21 is performed. In the speed class recording section, “CMD25” 800-2 and 800-4, which are data write commands, are issued from the host device to the SD memory card, and speed guarantee data to be written, such as the photographed moving image data, is transmitted.

Note that “CMD25” of the SD memory card standard is a command for performing data writing of multiple blocks (a plurality of blocks: n blocks=512×n bytes).

During continuous writing of the speed guarantee data to be written such as the photographed moving image data into the SD memory card, file system 108 of the host device shown in FIGS. 2 and 3 writes the appropriately updated FAT (file allocation table) according to the data in which the writing to the file has been completed into the SD memory card by issuing “CMD25” 800-3 and 800-5.

The “speed class recording section” ends when another write command (800-6) is issued.

As described above, the host device formulates in advance, in the memory card, the specification in which the host device notifies the SD memory card of the information instructing a shift to the optimal performance operation mode, so that the SD memory card operates with the minimum performance necessary for executing the speed guarantee recording, the power consumption of the memory card is suppressed low, and as a result, the heat generation of the host device and the SD memory card can be suppressed.

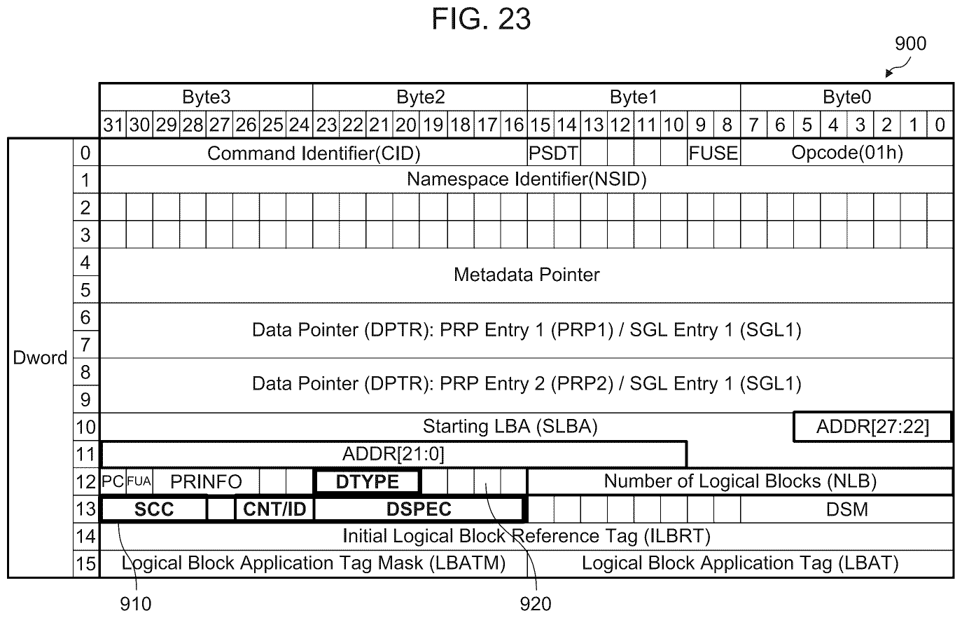

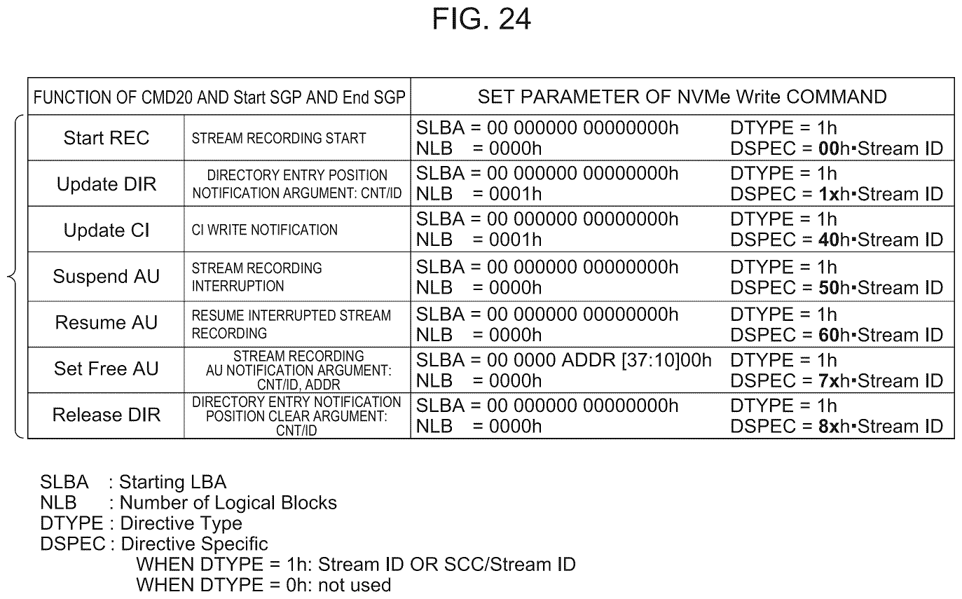

Note that, in the exemplary embodiment of the present invention, the method of using the “CMD20” of the SD memory card standard has been described as an example of the means for the host device to notify the memory card of the information instructing the shift to the optimal performance operation mode. However, as illustrated in FIGS. 23 and 24, the present inventor has devised a mechanism for implementing the function of “CMD20” of the SD memory card standard by a command conforming to the NVMe standard even in the memory card conforming to the NVMe standard, and accordingly, the host device can notify the memory card of the information instructing the shift to the optimal performance operation mode.

Specifically, the SCC, the CNT/ID, and the ADDR in the “CMD20” of the SD memory card standard illustrated in FIG. 18 are directly allocated to the bits “31” to “28” of Dword “13” (4-bit region), the bits “26” to “24” of Dword “13” (3-bit region), and the bits “5” to “0” of Dword “10” and the bits “31” to “10” of Dword “11” (28-bit region in total) in the Write command (data write command) belonging to the NVM command set of the NVMe standard illustrated in FIG. 23, respectively.

Note that, in the NVMe standard, two types of command sets, namely, an admin command set and an NVM command set, are defined. The admin command set is a control command group in which a recording device mainly reads information related to a function, performance, and specification of a non-volatile storage device or performs various settings of the non-volatile storage device, and the NVM command set is a command group related to data such as writing data to a non-volatile memory of the non-volatile storage device or reading data from the non-volatile memory.

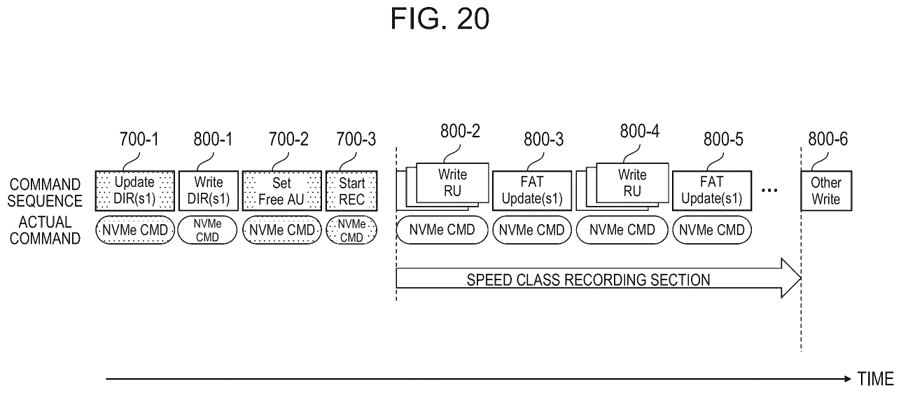

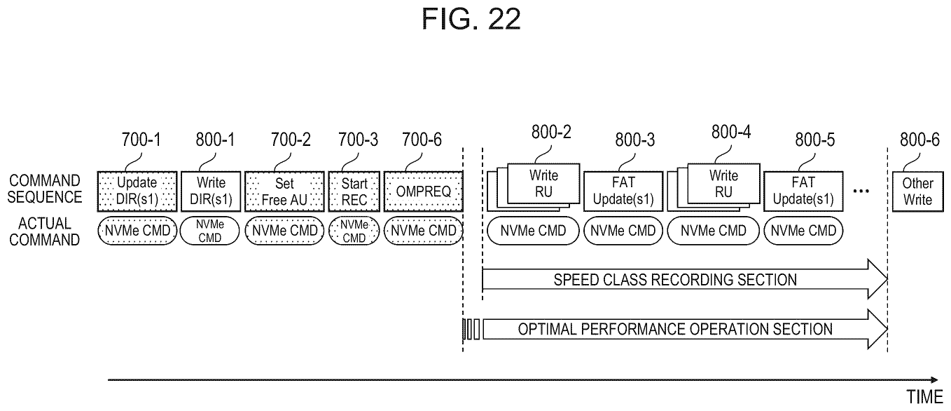

As described above, by directly allocating the function of “CMD20” in the SD memory card standard to the command conforming to the NVMe standard, it is possible to perform the speed guarantee recording control by the command conforming to the NVMe standard as illustrated in FIGS. 20 and 22 without changing the command sequence at the time of the speed guarantee recording in the SD memory card illustrated in FIGS. 19 and 21.

Because the SCC, CNT/ID, and ADDR in “CMD20” of the SD memory card standard are directly allocated to the Write command (data write command) of the NVMe standard illustrated in FIG. 23, the NVMe CMD (NVMe command) in FIGS. 20 and 22 are all the Write commands (data write commands) of the NVMe standard.

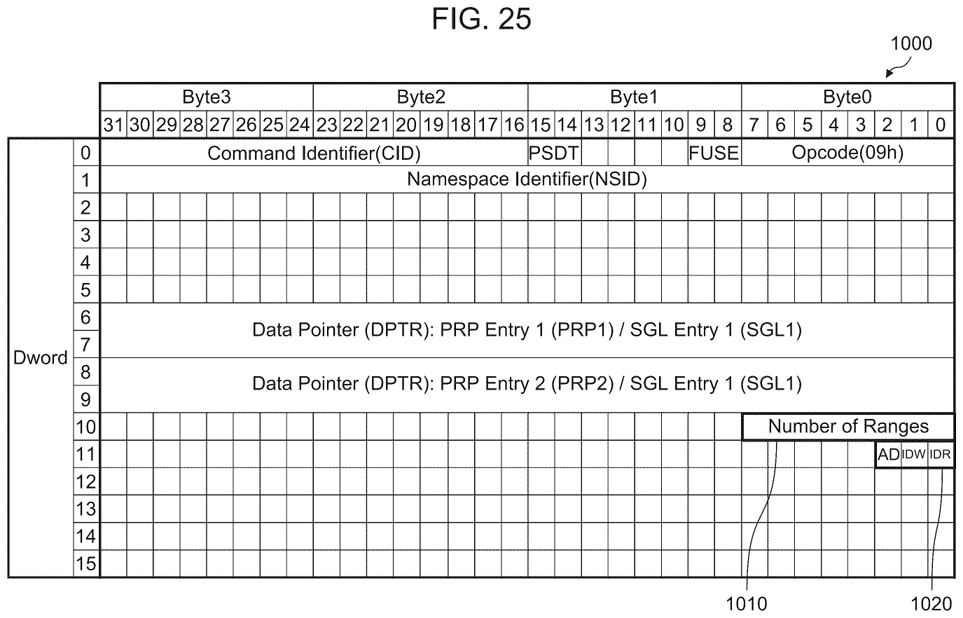

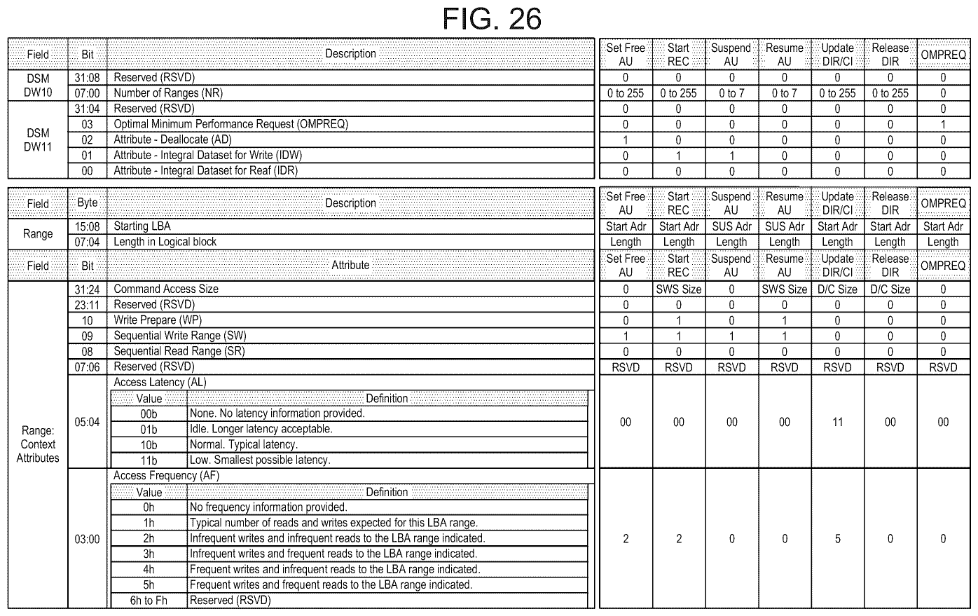

In addition, as another mechanism for implementing the function of “CMD20” in the SD memory card standard by a command conforming to the NVMe standard, a method for allocating eight functions of the SCC in “CMD20”, that is, Start REC, Update DIR, Update CI, Suspend AU, Resume AU, Set Free AU, Release DIR, and OMPREQ illustrated in FIG. 18 to the NVMe command according to setting states of various parameters in the NVMe command has also been devised. (Note that either the present method illustrated in FIGS. 25 and 26 or the method of directly allocating the function of “CMD20” in the SD memory card standard illustrated in FIGS. 23 and 24 to a command conforming to the NVMe standard is adopted.)

Specifically, the mechanism is a mechanism for uniquely performing identification by setting values of Number of Ranges (bit “7” to bit “0”) of Dword “10”, AD (attribute-deallocate) (bit “2”) of Dword “11”, IDW (attribute-integral dataset for write) (bit “1”), IDR (attribute-integral dataset for read) (bit “0”), and setting values such as attribute information of Range set in a list of Range stored in a Data Pointer (memory address such as main memory of recording device 10) of Dword “6” to Dword “9” in the Dataset Management command (hereinafter, abbreviated as a “DSM command”) belonging to the NVM command set of the NVMe standard illustrated in FIG. 25.

FIG. 26 is a table illustrating a correspondence example between the setting values such as the values set in Dword “10” and Dword “11” of the DSM command of the NVMe standard, and the list of Range, and the attribute information of Range set in the list of Range, and the eight functions of the SCC in the “CMD20”.

Here, the attribute information of Range is 32-bit information expressed as “Range: Context Attributes” in the lower table on the left side of FIG. 26.

The eight functions of the SCC in the “CMD20” are uniquely defined by a combination of values set to Dword “10” and Dword “11” of the DSM command described in the table of FIG. 26, and the attribute information (Range: Context Attributes) of Range.

Note that Update DIR is a function of notifying the card of the position of the directory entry from the host, and Update CI is a function of notifying the card that the writing of CI (Continuous Information) is performed from the host. However, since both of the functions are functions for notifying the card that the writing of data having a small size is performed unlike continuous stream record data typified by moving image photographing such as a directory entry and a file allocation table (FAT), in the function correspondence table illustrated in FIG. 26, Update DIR and Update CI are combined into one function to be Update DIR/CI.

In addition, the instruction of shift to the optimal performance operation mode is performed by setting bit “03” of Dword “11” of the DSM command to “1”. That is, bit “03” of Dword “11” of the DSM command is allocated to the information “OMPREQ” (Optimal Minimum Performance Request) instructing the shift to the optimal performance operation mode. (Note that bits “31” to “03” of Dword “11” of the DSM command are unused (reserved) bits in NVM Express Base Specification Revision 1.4.)

As described above, in the exemplary embodiment of the present disclosure, the method of using the “CMD20” of the SD memory card standard has been described as an example of the means for the host device to notify the memory card of the information instructing the shift to the optimal performance operation mode. However, the present inventor has devised a mechanism for implementing the function of the “CMD20” of the SD memory card standard by a command conforming to the NVMe standard as illustrated in FIGS. 25 and 26 also for a memory card conforming to the NVMe standard, and accordingly, the host device can notify the memory card of the information instructing the shift to the optimal performance operation mode.

As a result, it is possible to perform the speed guarantee recording control by the command conforming to the NVMe standard as illustrated in FIGS. 20 and 22 without changing the command sequence at the time of the speed guarantee recording in the SD memory card illustrated in FIGS. 19 and 21.

SCC, CNT/ID, and ADDR in “CMD20” of the SD memory card standard are allocated to the DSM commands of the NVMe standard illustrated in FIGS. 25 and 26, respectively. Therefore, in the NVMe CMD (NVMe commands) of FIGS. 20 and 22, 700-1, 700-2, 700-3, and 700-6 are DSM commands, and 800-1, 800-2, 800-3, 800-4, and 800-5 arc Write commands (data write commands) of the NVMe standard.

In addition, in both the memory card conforming to the SD memory card standard and/or the memory card conforming to the NVMe standard, the host device can notify the memory card of information instructing the shift to the optimal performance operation mode by using a control command other than “CMD20” in the SD memory card standard or a command for performing writing in a control register, a NAND flash memory, or the like in the memory card.

For example, it is conceivable to use a control command for setting a power consumption limit of the SD memory card standard or a control command for performing power consumption management of the NVMe standard.

Here, as an example, a method of using “CMD6” of the SD memory card standard will be briefly described.

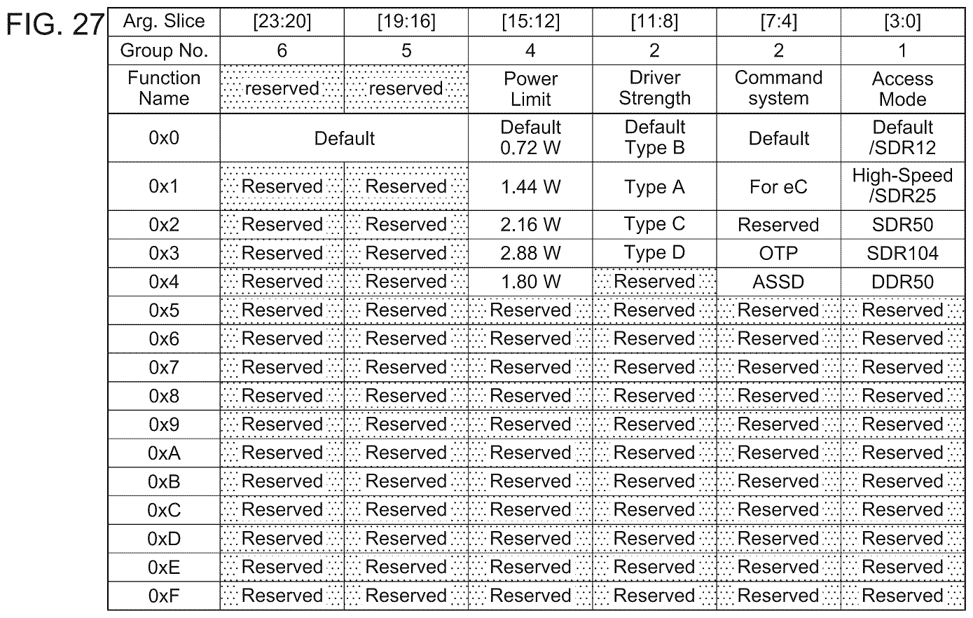

“CMD6” is a switch function command in a conventional SD memory card, and is a control command issued when power consumption limit of the SD memory card or switch of an interface mode is performed. FIG. 27 illustrates a data structure of the command argument (Argument: Arg. Slice) in “CMD6”. For example, switching among SDR25, DDR50, SDR50, and SDR104 which are the bus speed modes of UHS-I illustrated in FIG. 14 is instructed by bits “3” to “0” of the command argument of CMD6 illustrated in FIG. 27. That is, when 1 h is set to bit “3” to bit “0”, a switching instruction to SDR25 is instructed. Similarly, when 2 h is set to bit “3” to bit “0”, a switching instruction to SDR50 is instructed. When 3 h is set to bit “3” to bit “0”, a switching instruction to SDR104 is instructed. When 4 h is set to bit “3” to bit “0”, a switching instruction to DDR50 is instructed.

In addition, bit “15” to bit “12” of the command argument of CMD6 illustrated in FIG. 27 are bits for switching the power consumption limit. When Oh is set in bit “15” to bit “12”, an operation in a mode in which the maximum power consumption of the SD memory card is suppressed to 0.72 W or less is instructed. Thereafter, similarly, when 1 h is set in bit “15” to bit “12”, an operation in a mode in which the maximum power consumption is suppressed to 1.44 W or less is instructed. When 2 h is set in bit “15” to bit “12”, an operation in a mode in which the maximum power consumption is suppressed to 2.16 W or less is instructed. When 3 h is set in bit “15” to bit “12”, an operation in a mode in which the maximum power consumption is suppressed to 2.88 W or less is instructed. When 4 h is set in bit “15” to bit “12”, an operation in a mode in which the maximum power consumption is suppressed to 1.80 W or less is instructed.

Therefore, it is conceivable that the host device uses “CMD6” of the SD memory card standard to set power corresponding to the guaranteed speed as a means for instructing the shift to the optimal performance operation mode. That is, the process can be executed by replacing 700-6 “OMPREQ” in FIG. 21 with “CMD6” from “CMD20”.

Next, as another example of a method in which the host device notifies the memory card of information instructing a shift to the optimal performance operation mode, a method of using a control command for performing power consumption management of the NVMe standard will be briefly described.

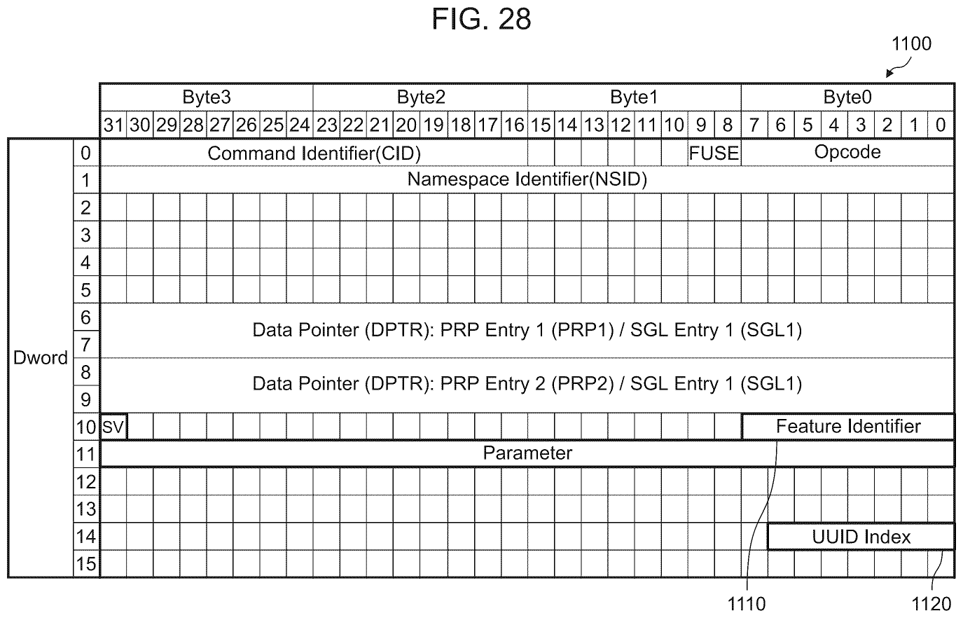

FIG. 28 is a diagram illustrating a data structure of a set features command belonging to an admin command set of the NVMe standard.

Bit “7” to bit “0” of Dword “10” in the set features command are feature identifiers and are fields for designating an identifier (ID) of a function to be set by the set features command.

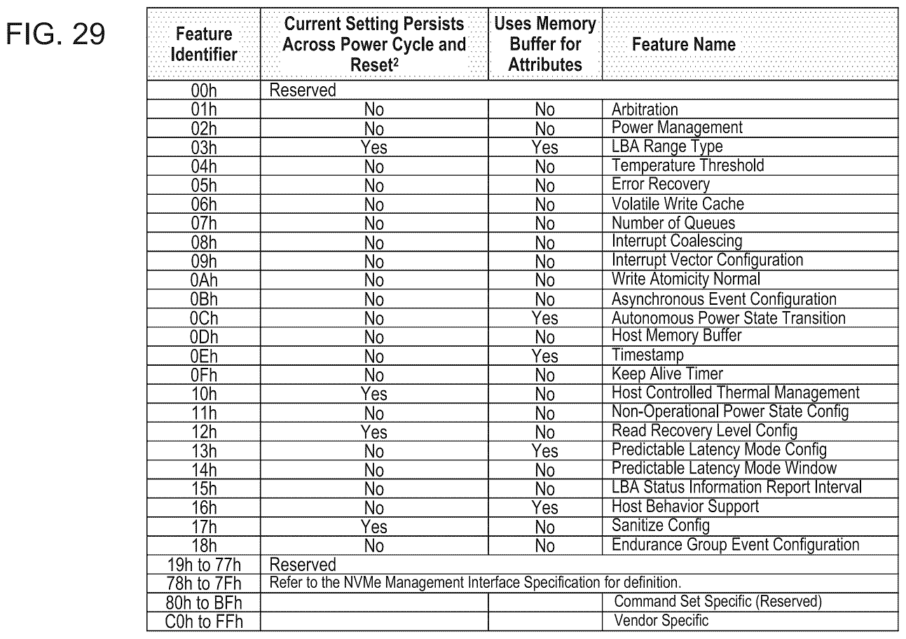

In addition, FIG. 29 illustrates a list of various functions to be set by the set features command and their feature identifiers (IDs).

Bit “31” to bit “0” of Dword “11” in the set features command are parameters. The parameter is defined for each function designated by the feature identifier (bit “7” to bit “0” of Dword “10”).

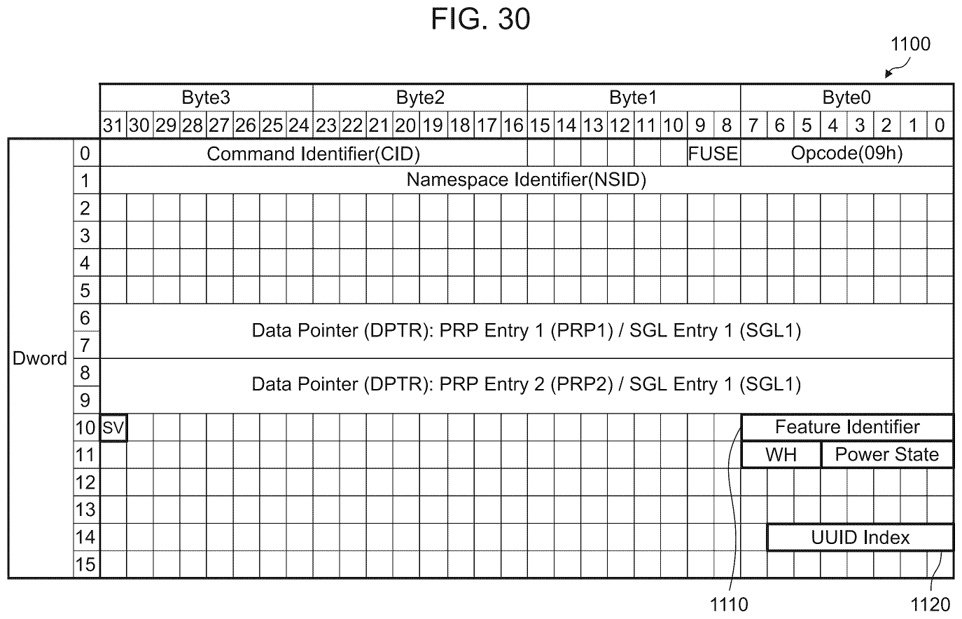

For example, the feature identifier “02 h” illustrated in FIG. 29 is Power Management (power consumption management function), and parameters of the Power Management (power consumption management function) are illustrated in FIG. 30.

Bit “7” to bit “5” of Dword “11” illustrated in FIG. 30 are WH (workload Hint) and are parameters for notifying the non-volatile storage device of reference information regarding the processing amount such as how many times writing to the non-volatile memory occurs, and bit “4” to bit “0” of Dword “11” are Power States (power consumption states) and are used to designate and operate a certain power consumption state among a plurality of power consumption states supported by the non-volatile storage device.

Therefore, it is conceivable that the host device uses Power Management (power consumption management function) of the set features command of the NVMe standard to set the power consumption state corresponding to the guaranteed speed as a means for instructing the shift to the optimal performance operation mode. That is, 700-6 “OMPREQ” in FIG. 22 can be executed by the set features command.

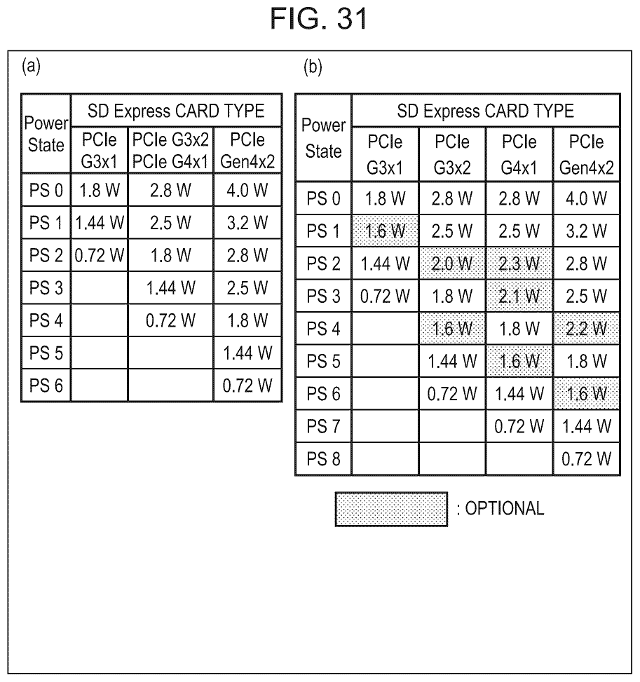

Here, a plurality of power consumption states supported by the non-volatile storage device will be described with reference to FIG. 31.

FIG. 31(a) illustrates a power consumption state for each SD Express card type which is required to be included in the card in the SD standard.

There are four types of SD Express card types, which are a card including Gen3 (third generation)×1 lane of the PCIe interface (expressed as “PCIe G3×1” in the drawing), a card including Gen3 (third generation)×2 lanes of the PCIe interface (expressed as “PCIe G3×2” in the drawing), a card including Gen4 (fourth generation)×1 lane of the PCIe interface (expressed as “PCIe G4×1” in the drawing), and a card including Gen4 (fourth generation)×2 lanes of the PCIe interface (expressed as “PCIe G4×2” in the drawing).

PCIe G3×1 card and PCIe G4×1 card corresponding to one lane of the PCIe interface include the terminals illustrated in FIG. 6, and PCIe G3×2 card and PCIe G4×2 card corresponding to two lanes of the PCIe interface include the terminals illustrated in FIG. 7.

Here, since the data transmission path of the PCIe standard Gen4 realizes twice the speed of the data transmission path of Gen3, PCIe G3×2 (card including two lanes of Gen3) and PCIe G4×1 (card including one lane of Gen4) among the SD Express card types have the same interface speed as the card (non-volatile storage device).

For this reason, as illustrated in FIG. 31(a), the SD standard specifies that card type PCIe G3×2 and card type PCIe G4×1 have the same five required power consumption states.

As described above, FIG. 31(a) illustrates a power consumption state for each SD Express card type that is required to be included in the card in the SD standard, and FIG. 31(b) illustrates an example of a power consumption state included in an actual SD Express card.

Regarding the specification related to the power consumption state, in the NVMe standard that the SD standard refers to and conforms to, the card (non-volatile storage device) can include up to 32 power consumption states.

Therefore, also in the SD standard, in addition to the SD standard required power consumption state for each card type illustrated in FIG. 31(a), an optional power consumption state can be provided up to 32 together with the required power consumption state.

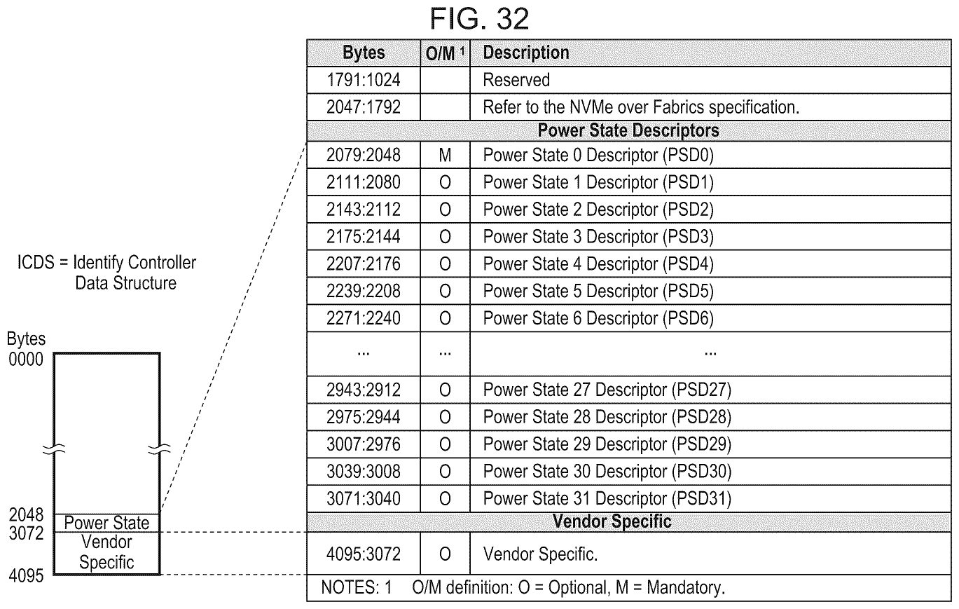

In the NVMe standard, as illustrated in FIG. 32, a specification indicating a power consumption state included in a card is defined from 2048 bytes to 3071 bytes of a 4,096-byte identify controller data structure read from the card by an identify command issued from the host device to the card.

Further, in the NVMe standard, the card can have up to 32 power consumption states (Power States 0 to 31), but it is sufficient that the card has at least one power consumption state.

That is, the required power consumption state is 1, and as illustrated in FIG. 32, the power consumption state 0 (Power State 0) is M (Mandatory)=Required, and the power consumption states 1 to 31 (Power States 1 to 31) are O (Optional).

Here, the SD standard will be described again. FIG. 31(b) illustrates, for example, an example in which the PCIe G3×1 card has an optional power consumption state of 1.6 W in addition to 1.8 W, 1.44 W, and 0.72 W which are required power states defined by the SD standard.

Note that, in the figure (table), the power consumption state indicated by hatching is not required in the SD standard, that is, the power consumption state in which the card (non-volatile storage device) is provided as one implementation (one design) and is positioned as optional in the SD standard is indicated, and the power consumption state without hatching is indicated as the power consumption state which is required for each card type in the SD standard.

Similarly, FIG. 31(b) illustrates that the example of the PCIe G3×2 card includes the optional power consumption states of 2.0 W and 1.6 W in addition to 2.8 W, 2.5 W, 1.8 W, 1.44 W, and 0.72 W which are the required power consumption states defined by the SD standard, the example of the PCIe G4×1 card includes the optional power consumption states of 2.3 W, 2.1 W, and 1.6 W, and the example of the PCIe G4×2 card includes the optional power consumption states of 2.2 W and 1.6 W.

As described above, the number of power consumption states and the power value included in the card (non-volatile storage device) are different for each individual manufacturer and each individual product.

Therefore, the host device needs to know in advance the number of power consumption states included in the card attached to the host device and the power values of the respective power consumption states in a phase called initialization immediately after power is turned on to the card.

The host device can read the number of power consumption states included in the card and the respective power consumption values from the card by an identify command belonging to the admin command set of the NVMe standard.

As illustrated in the left diagram in FIG. 32, the number of power consumption states included in the card is indicated by a range of 1 to 32 as Number of Power States Support (NPSS) in 263 bytes of 4,096 byte-identify controller data structure read from the card by the host device with the identify command.

Note that, in the allocation table in byte units on the right side of FIG. 32, Number of Power States Support (NPSS) of the 263Byte is omitted, but detailed specifications can be confirmed by referring to the NVMe standard specification.

As illustrated in FIG. 32, the power consumption value of each of the power consumption states included in the card is indicated in 2,048 to 3,071 Byte of the 4,096-byte identifier controller data structure read from the card by the identify command.

Specifically, information of 32 bytes (256 bits) is indicated for one power consumption state (Power State), a power value is stored as Maximum Power (MP) in lower 2 bytes (Bits15 to 0) among 32 bytes, and a scale of the Maximum Power (MP) is indicated as Max Power Scale (MXPS) in Bit24, so that the power in watt units can be obtained by multiplying the value of the MP by the scale indicated by MXPS.

When MXPS is 0, the scale of MP is 0.01 watts, and when MXPS is 1, the scale of MP is 0.0001 watts.

The NVMe standard describes the above-described identify command, an identifier controller data structure read by the identify command, and detailed specifications regarding the number of power consumption states (NPSS) and the power consumption value (MXPS×MP) included in the identifier controller data structure, and thus detailed descriptions thereof will be omitted herein.

As described above, the host device reads the information on the number of power consumption states included in the card and the power consumption value from the card, and then designates (sets) a desired power consumption state for the card.

Specifically, a Power State value is set to bit “4” to bit “0” of Dword “11” in the set features command illustrated in FIG. 30, and the command is issued to the card.

For example, when a power consumption state of 1.8 W (Power State 4) is set for the PCIe G4×1 card of FIG. 31(b), a Power State value “4” is set to bit “4” to bit “0” of Dword “11” in the set features command illustrated in FIG. 30, and a command is issued to the card.

As illustrated in FIGS. 31(a) and 31(b), the power consumption state is allocated with consecutive numbers (Power State value) starting from 0 such that each subsequent power consumption state is equal to or less than the power of the previous state. Therefore, power consumption state 0 (Power State 0 (PS0)) indicates the maximum power consumption that can be consumed by the SD Express card.

Here, problems when the host device instructs a shift to the optimal performance operation mode will be described.

As described above, the card can include a plurality of power consumption states, and the number of power consumption states included in the card and the power consumption value of each power consumption state are different for each manufacturer and each card.

The host device can know the number of power consumption states included in the card and the power consumption value of each power consumption state by issuing an identify command.

On the other hand, in a case where data such as a moving image is recorded in a card (non-volatile storage device) at a desired guaranteed speed, the host device does not have a method of knowing the power consumption required by the card. Therefore, in the power consumption state designated for the card by issuing the set features command by the host device, there is a problem that the power is insufficient to perform recording in the card (non-volatile storage device) at the desired guaranteed speed, and the speed guarantee recording cannot be correctly performed, or conversely, the card consumes power equal to or more than the power required to perform recording in the card at the desired guaranteed speed, and as a result, the temperature of the card increases, and the speed guarantee recording cannot be continued.

Therefore, the present inventor has studied a new mechanism for notifying a host device of a power consumption state for operating the card while reducing its performance to a performance necessary and sufficient for recording data such as a moving image in a card at a desired guaranteed speed from the card.

As described above, in the NVMe standard, the number of power consumption states included in the card is indicated in 263Byte of a 4,096-byte identify controller data structure read from the card by an identify command, as Number of Power States Support (NPSS) in a range of 1 to 32 states. Further, as illustrated in FIG. 32, the power consumption value of each power consumption state included in the card is indicated in 2,048 to 3,071Byte of a 4,096-byte identify controller data structure read from the card by an identify command.

In addition, a mechanism has been devised in which information for notifying a host device of a power consumption state from a card (non-volatile storage device) for operating the card at a performance necessary and sufficient for recording data such as a moving image in the card at a desired guaranteed speed is newly allocated to a Vendor Specific area secured in 3072Byte to 4095Byte of an identify controller data structure, and the information is indicated to the host device.

FIG. 32 illustrates the Vendor Specific area of the identify controller data structure.

As illustrated in FIG. 32, the Vendor Specific area is allocated to 3072Byte to 4095Byte.

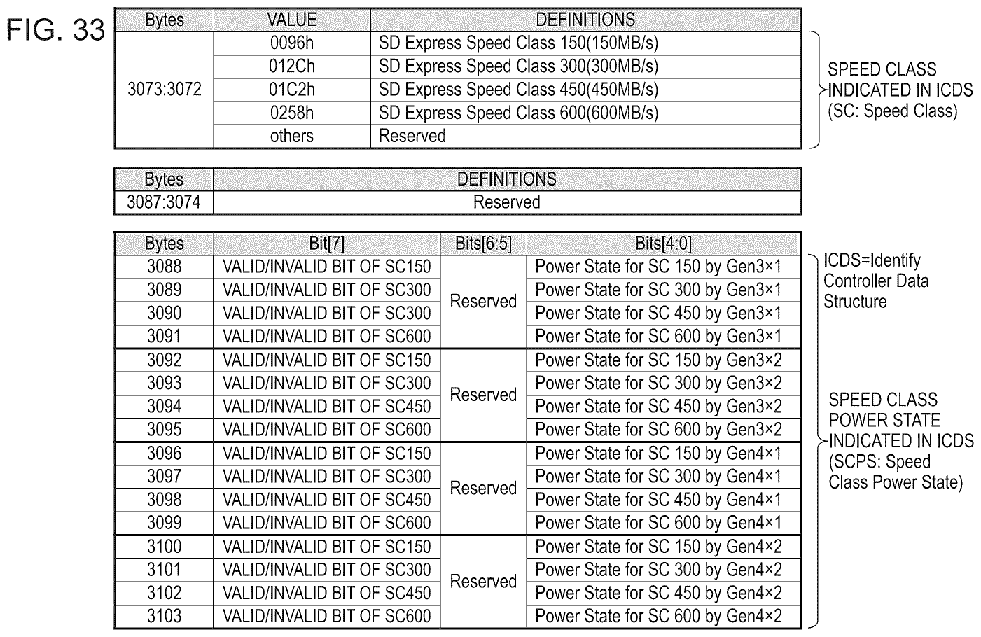

FIG. 33 is a diagram illustrating an example of information to be newly allocated to the area. In the present exemplary embodiment, first, the value of the speed guarantee class (SD Express speed class) corresponding to the card is indicated in 3072Byte to 3073Byte of the Vendor Specific area.

For example, as illustrated in FIG. 16, when the Gen3×1 card conforms to speed guarantee class 150 (150 MB/s), class 300 (300 MB/s), and class 450 (450 MB/s) but does not conform to class 600 (600 MB/s), 01C2h (=450 (decimal number)) is displayed in 3072Byte to 3073Byte of the Vendor Specific area.

The value indicated here is the speed value itself of the fastest speed guarantee class corresponding to the card.

Further, in the SD standard, in order to ensure backward compatibility, the card is required to support a speed guarantee class lower than the speed guarantee class described here.

That is, in a case where the card notifies 01C2h (=450 (decimal number)), it indicates that the card supports class 450 (450 MB/s), and also the lower classes 300 (300 MB/s) and 150 (150 MB/s).

Next, in 3088Byte to 3103Byte of the Vendor Specific area, a combination of the speed guarantee class and the bus mode, and minimum power consumption states necessary and sufficient for the card in the combination are defined as areas indicated to the host device.

Bit[7] (MSB: most significant bit) in each byte of 3088 to 3103 indicates to which bus mode and speed guarantee class the card (non-volatile storage device) corresponds, and “0” indicates invalid, that is, not corresponding, and “1” indicates valid, that is, corresponding.

Hereinafter, a Gen4×1 card will be described as an example.

The Gen4×1 card includes Gen4×1 and Gen3×1 as bus modes.

In the SD standard, in order to maintain backward compatibility, a card with a faster bus mode needs to correspond to a bus mode with a lower speed.

However, since the Gen4×1 card includes only one row of terminal county for PCIe as illustrated in FIG. 6, the Gen4×1 card does not correspond to Gen3×2.

On the other hand, since the Gen4×2 card includes two rows of terminal groups for PCIe as illustrated in FIG. 7, the Gen4×2 card corresponds to all four bus modes of Gen4×2, Gen4×1, Gen3×2, and Gen3×1 as bus modes.

Therefore, regarding the Gen4×1 card, “0”, that is, “invalid (not corresponding)” is displayed in Bit[7] (MSB: most significant bit) in each byte of 3092˜3095 (area of combination of Gen3×2 and each SC (speed guarantee class)) and 3100˜3103 (area of combination of Gen4×2 and each SC (speed guarantee class)) indicating the Power State of the bus mode in which two rows of the PCIe terminal groups illustrated in FIG. 7 are required.

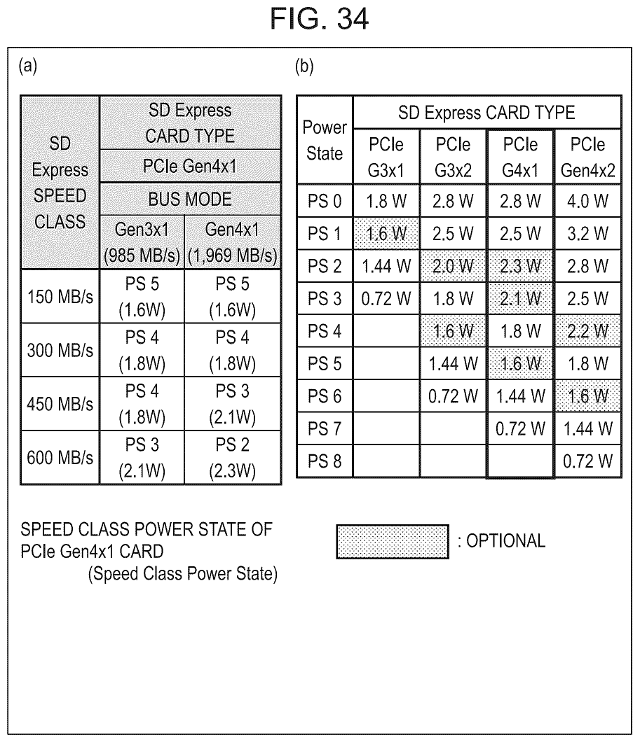

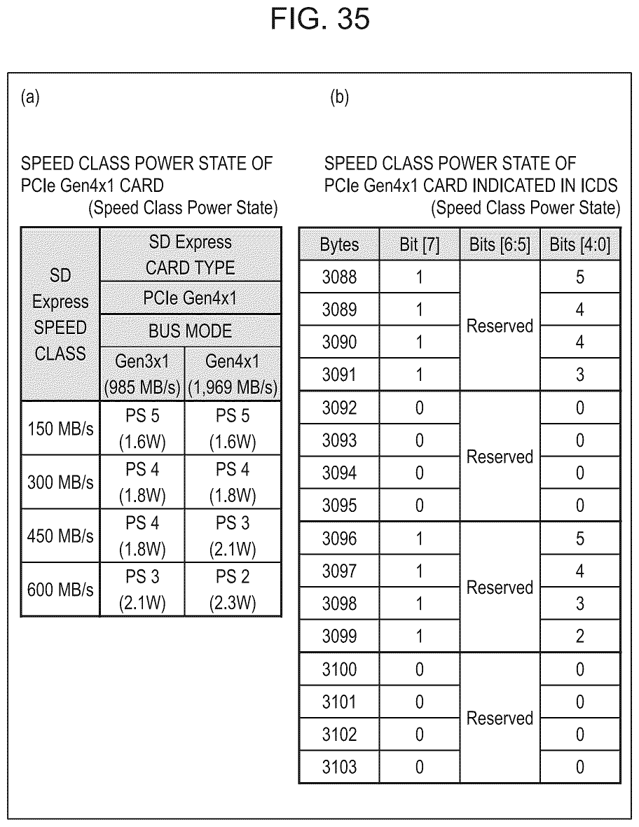

Hereinafter, an example of the Gen4×1 card will be described in more detail with reference to FIGS. 34 and 35.

FIG. 34(b) is the same as FIG. 31(b).

In the example in which the Gen4×1 card includes the five required power consumption states (2.8 W, 2.5 W, 1.8 W, 1.44 W, 0.71 W) and the three optional power consumption states (2.3 W, 2.1 W, 1.6 W) defined in the SD standard as illustrated in FIG. 34(b), when the card conforms to all of the four speed guarantee classes (SD Express speed class), namely, the “class 150” of 150 MB/s, the “class 300” of 300 MB/s, the “class 450” of 450 MB/s, and the “class 600” of 600 MB/s, an example of the minimum power consumption necessary and sufficient for executing the moving image recording in each SC (speed guarantee class) in the bus mode of Gen3×1 and Gen4×1 is illustrated in FIG. 34(a).

As illustrated in FIG. 34(a), for each card type and each bus mode, the minimum power consumption state necessary and sufficient for performing the speed guarantee recording of each speed guarantee class (speed class) is defined as “Speed Class Power State”.

For example, in the bus mode Gen4×1, the speed class power state when the speed guarantee recording of the class 600 is executed is PS2, and in comparison with FIG. 34(b), it can be seen that 2.3 W is the necessary, sufficient, and minimum power.

Similarly, the speed class power state when the speed guarantee recording of the class 450 is executed is PS3, and in comparison with FIG. 34(b), it can be seen that 2.1 W is the necessary, sufficient, and minimum power.

Hereinafter, the speed class power state when the speed guarantee recording of the class 300 is executed is 1.8 W of PS4, and the speed class power state when the speed guarantee recording of the class 150 is executed is 1.6 W of PS5.

Note that, in a case where the “class 600” speed guarantee recording of 600 MB/s is performed in the same Gen4×1 card, 2.3 W of PS2 is required in the Gen4×1 bus mode in which the interface speed (bus speed) is faster, whereas in the Gen3×1 bus mode, 2.1 W of PS3 is required, even in a case where the same “class 600” recording is performed, it is also indicated in the present exemplary embodiment that the operation can be performed with more power saving.

Next, FIG. 35(b) illustrates an example in which the speed class power state of the Gen4×1 card is notified to the host device in the Vendor Specific area of 3088Byte to 3103Byte of an identify controller data structure (ICDS).

Note that FIG. 34(a) is illustrated again in FIG. 35(a) for easy understanding of the correspondence with FIG. 35(b).

As described above, since the Gen4×1 card cannot support the bus modes of Gen4×2 and Gen3×2, a value “0” indicating that Bit [7] of 3092Byte to 3095Byte and 3100Byte to 3103Byte is “invalid” is stored and notified.

On the other hand, since the Gen4×1 card is an example conforming to all four speed classes in two bus modes of Gen4×1 and Gen3×1, a value “1” indicating that Bit [7] of 3088Byte to 3091Byte and 3096Byte to 3099Byte is “valid” is stored and notified.

In addition, the state value itself of the speed class power state illustrated in FIGS. 34(a) and 35(a) is stored in Bits “4:0” of 3088Byte to 3091Byte and 3096Byte to 3099Byte and is notified.

As described above, in the present disclosure, a mechanism for notifying a host device of a minimum power consumption state necessary and sufficient for a card to perform speed guarantee recording has been newly devised and defined.

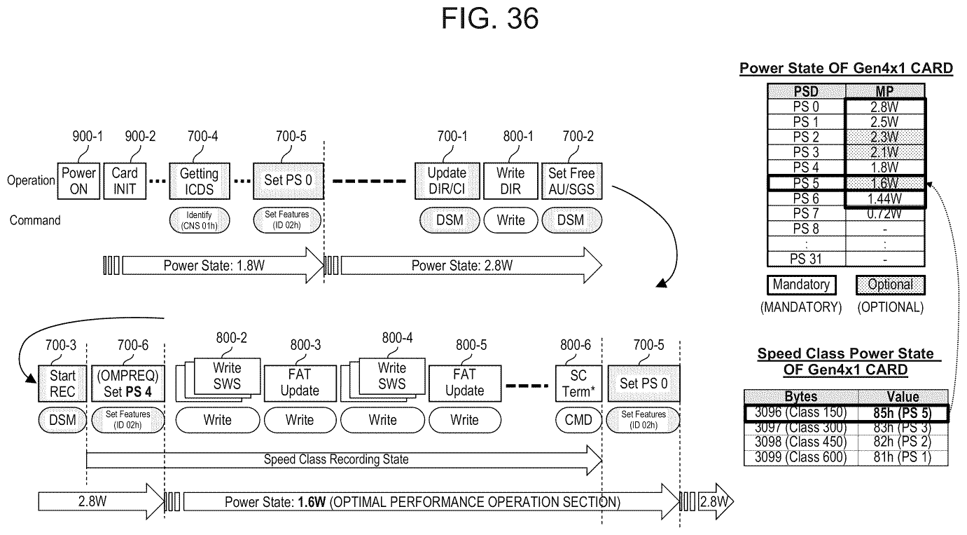

Next, a procedure (sequence) in a case where the host device acquires the speed class power state of the card from the card and sets the power state conforming to the desired guaranteed speed before starting the speed guarantee recording will be described with reference to FIG. 36.

FIG. 36 illustrates an example of a command sequence at the time of speed guarantee recording in the SD Express card. In FIG. 36, a horizontal axis represents time, and recording device 100 issues a command to memory card 200 in order from a left side to a right side of the drawing.

In the example illustrated in FIG. 36, quadrangular symbols (sequence shape elements) indicated by 700-1 to 700-6, 800-1 to 800-6, and 900-1 to 900-2 indicate functions of commands transmitted from the host device to the SD Express card.

In addition, an actual command name is described in an elliptical symbol (sequence shape element) described below the quadrangular symbol, and in the example of FIG. 36, all the commands are MVMe standard commands.

Note that the basic sequence when the speed guarantee recording is performed is described with reference to FIG. 22, and thus the description thereof is omitted here.

In addition, a method of implementing the function of each command by a DSM (Dataset Management) command of NVMe follows the specification described with reference to FIG. 26.

FIG. 36 is obtained by adding the following processing to the basic sequence in performing the speed guarantee recording illustrated in FIG. 22.

In 900-1 (Power On), the host device powers on (supplies power to) the SD Express card attached to the host device.

At 900-2, the host device executes initialization processing of the SD Express card.

Here, the initialization processing is processing in which the host device reads, from the card, the function and performance corresponding to the card, information unique to the card such as the manufacturer ID, and the like, and then the host device performs setting related to the function, performance, and the like used by the host device on the card.

700-4 denotes issuance of an identify command executed as a part of the above-described initialization processing, and with this command issuance, the host device reads an identify controller data structure (ICDS) including 4,096 bytes from the card.

The ICDS notifies the host device of the number of power consumption states included in the card defined in the NVMe standard and the power consumption value of each of the power consumption states from the card.

In addition, the SC (speed class=speed guarantee class) and the SCPS (speed class power state) formulated by the present inventor is notified from the card to the host device.

In 700-5, the host device issues an identify command 700-4 to set the maximum power consumption state of the Gen4×1 card with a set features command based on the number of power consumption states in the ICDS acquired from the Gen4×1 card and the respective power consumption values of the power consumption states.

By setting the maximum power consumption state, when high-speed continuous shooting such as 20 frames/sec is performed simultaneously on still image RAW data (unprocessed data) having very high pixels and still image JPEG data (compressed data) with a digital single lens reflex camera or the like, recording with the highest speed performance of the memory card can be performed.

Here, the RAW data refers to unprocessed image data output from the image sensor, and is raw data of the image sensor that cannot be viewed as a photographed photograph unless color restoration processing or the like is performed.

In order to visually confirm a photograph photographed by a user of a digital camera, JPEG data subjected to data compression by processing such as color restoration processing from RAW data and processing of thinning out information on intensity of light is generally recorded together with RAW data.

Therefore, for example, in high-speed continuous shooting at 20 frames/sec, it is necessary to record RAW data for 20 images per second and JPEG data for 20 images in total, and recording in a very high-speed memory card is required.

On the other hand, regarding moving image photographing, a codec having a high compression rate by an algorithm more suitable for moving image data such as MPEG is widely adopted, and for example, by a method of recording difference information between a moving image frame serving as a reference (one frame of a moving image) and subsequent moving image frames, the recording rate in the memory card is suppressed to be low as compared with high-speed continuous shooting of still images.

The default power consumption state (initial power state after power is turned on) of the SD Express card is defined as 1.8 W in the SD standard.

Therefore, the PS (power consumption state) of the Gen4×1 card is switched from PS4 (1.8 W) to PS0 (2.8 W) by the set features command of 700-5.

700-1, 800-1, 700-2, and 700-3 are the same processing as the symbols with the same numbers (sequence shape elements) illustrated in FIGS. 19, 20, 21, and 22, and thus the description thereof is omitted.

700-6 denotes issuance of a command for giving a notification of information “OMPREQ” (Optimal Minimum Performance Request) instructing a shift to the optimal performance operation mode illustrated in FIG. 22.

In the present disclosure, the host device issues a set features command to the Gen4×1 card, and thereafter notifies the Gen4×1 card to operate in the power consumption state of PS5 (1.8 W) in order to perform the speed guarantee recording of class 150.

As a result, the Gen4×1 card shifts to a minimum power consumption state necessary and sufficient to perform the speed guarantee recording of 150 MB/s, that is, an optimal performance operation mode.

As described above, the host device can set, from the card, a sufficient and optimal (minimum) power consumption state necessary for the card to perform (desired speed class) recording of the speed desired by the host device on the basis of the number of power consumption states included in the card, the power consumption value of each of the power consumption states, and the information of the speed class and the speed class power state illustrated in FIG. 33 and the like newly devised and defined in the present disclosure.

Finally, a specific example in which the non-volatile storage device operates in the power consumption state corresponding to the guaranteed speed will be briefly described. Here, in the non-volatile storage device including the SD memory card on which the NAND flash memory (non-volatile memory) is mounted, in general, the total power consumption of CPU 212, buffer memory 216, and NAND controller 218 inside controller 210 illustrated in FIGS. 2 and 3 and the power consumption of NAND flash memory 220 are much larger than the power consumption of PCIe interface 214a, SD interface 214b, UHS-II interface 314a, or SD interface 314b with the host device (recording device 100) illustrated in FIGS. 2 and 3.

For example, in the circuit implementation example of the PCIe interface 214a of FIG. 2, there is a semiconductor power simulation result report in which the power consumption is 61 mW. On the other hand, as illustrated in FIG. 14, the maximum power consumption of the SD Express card including the PCIe interface is 4.00 W, which is about 65 times the power consumption of the PCIe interface 214a.

These circuit blocks in controller 210 and the NAND flash memory normally operate with a clock multiplied and/or divided based on the clock generated (transmitted) by oscillator 219 illustrated in FIGS. 2 and 3.

In order to suppress power consumption as low as possible, for example, when a command from a host device (recording device 100) is not issued for a certain period of time, controller 210 generally includes a mechanism for shifting to a plurality of power saving modes by dividing a clock supplied to a circuit block inside controller 210 or the like to gradually lower a clock frequency.

Therefore, it is possible to consider an implementation in which before Power Management (power consumption management function) setting 700-6 (OMPREQ) of the set features command is received, the clock supplied to the circuit block in controller 210 is set to the maximum clock frequency and operated, and in the “optimal performance operation section” after Power Management (power consumption management function) setting 700-6 (OMPREQ) of the set features command is received, the clock frequency is lowered so as to satisfy the setting value of the power consumption state corresponding to the guaranteed speed, that is, the clock frequency is lowered to the minimum clock frequency necessary for executing the speed guarantee recording.

Note that, as the means for instructing the shift to the optimal performance operation mode, a case where the host device uses the SD interface or the UHS-II interface and uses the command conforming to the SD protocol and a case where the host device uses the PCIe interface and uses the command conforming to the NVMe protocol have been described. However, the speed of the interface is faster in the PCIe interface than in the SD interface and the UHS-II interface, and as a result, the power consumption is larger in the case of using the PCIe interface.

For example, as illustrated in FIG. 14, while the maximum bus speed is 312 megabytes/sec in bus speed mode “UHS-II HD 312”, the maximum bus speed is 3,938 megabytes/sec in “SD Express PCIe Gen4×2”, and the speed (bus speed) is 12 times or more. Similarly, as illustrated in FIG. 14, while the maximum power consumption is 1.80 W in bus speed mode “UHS-II HD 312”, the maximum power consumption is 4.00 W in “SD Express PCIe Gen4×2”, which is twice or more the power consumption.

For these reasons, it is also conceivable that the optimal performance operation mode is valid only when data recording is performed in accordance with the protocol of the NVMe standard by using a PCIe interface having a greater effect.

### Outlines of Exemplary Embodiment

(1) A recording device of the present disclosure is a recording device that records data in a non-volatile storage device in a recording mode in which a minimum recording speed is guaranteed. The non-volatile storage device is attachable to and detachable from the recording device, and includes a memory that performs data recording conforming to the NVMe standard and/or the SD memory card standard.

In the memory, a recording speed is guaranteed for continuous stream recording.

The recording device includes an interface unit physically connected to the non-volatile storage device and capable of transmitting at least a data write command and a control command to the non-volatile storage device.

The interface unit can transmit a data write command instructing data recording and a control command including a command for instructing speed guarantee recording and/or a command for reading and writing a register in the non-volatile storage device.

The control command includes information instructing a shift to the optimal performance operation mode at the time of continuous stream recording.

The interface unit transmits a control command to the non-volatile storage device to instruct speed guarantee recording and notify information instructing a shift to the optimal performance operation mode, and transmits data for performing continuous stream recording by a data write command.
(2) The non-volatile storage device of the present disclosure is a non-volatile storage device capable of recording data in a recording mode in which a minimum recording speed is guaranteed.

The non-volatile storage device is attachable to and detachable from the recording device.

The non-volatile storage device includes a memory, an interface unit that communicates with the recording device, and a memory controller that performs data recording conforming to the NVMe standard and/or the SD memory card standard on the memory.

In the memory, a recording speed is guaranteed for continuous stream recording.

The non-volatile storage device includes an interface unit physically connected to the recording device and capable of receiving at least a data write command and a control command from the recording device.

The interface unit can receive, from the recording device, a data write command instructing data recording and a control command including a command for instructing speed guarantee recording and/or a command for reading and writing a register in the non-volatile storage device.

The control command includes information instructing a shift to the optimal performance operation mode at the time of continuous stream recording.

The interface unit receives a control command, and then receives a data write command instructing data recording and the data.

The memory controller shifts to an operation mode necessary and sufficient for guaranteeing the speed based on the information instructing the shift to the optimal performance operation mode included in the control command, and performs continuous data recording based on the data write command.
(3) A recording method of the present disclosure is a recording method executed in a recording device that records data in a non-volatile storage device in a recording mode in which a minimum recording speed is guaranteed.

The non-volatile storage device is attachable to and detachable from the recording device, and includes a memory that performs data recording conforming to the NVMe standard and/or the SD memory card standard.

In the memory, a recording speed is guaranteed for continuous stream recording.

The recording device includes an interface unit physically connected to the non-volatile storage device and capable of transmitting at least a data write command and a control command to the non-volatile storage device.

The interface unit can transmit a data write command instructing data recording and a control command including a command instructing speed guarantee recording and/or a command for reading and writing a register in the non-volatile storage device.

The control command includes information instructing a shift to the optimal performance operation mode at the time of continuous stream recording.

The recording method includes transmitting, by an interface unit, a control command to a non-volatile storage device to instruct speed guarantee recording and notify information instructing a shift to the optimal performance operation mode, and transmitting, after transmitting the control command, a data write command instructing continuous data recording and the data.

Note that, since the above-described exemplary embodiments are intended to illustrate the technique in the present disclosure, various changes, replacements, additions, omissions, and the like can be made within the scope of the claims or equivalents thereof.

For example, in the above-described exemplary embodiment, as illustrated in FIGS. 21 and 22, “OMPREQ” is provided as a new command, but may be integrated into “StartREC”.

The present disclosure can be suitably used in a storage system using a recording device that is a host device and non-volatile storage device 20.

What is claimed is:

1. A recording device that records data in a non-volatile storage device at a guaranteed minimum recording speed, the recording device comprising:
an interface unit physically connected to the non-volatile storage device and having a transfer speed higher than the minimum recording speed, wherein
the interface unit
is configured to transmit a control command to the non-volatile storage device, the control command including a data write command instructing data recording, a command instructing speed guarantee recording, and a command instructing a shift to an optimal performance operation mode, and
transmits the data write command instructing data recording after transmitting the command instructing the speed guarantee recording and the command instructing the shift to the optimal performance operation mode.

2. The recording device according to claim 1, wherein a recording speed of the optimal performance operation mode is faster than the minimum recording speed and slower than a maximum transfer speed by the interface unit.

3. The recording device according to claim 1, wherein
the interface unit conforms to an NVM Express (NVMe) standard, and
the command instructing the optimal performance operation mode is a data set management command of the NVMe standard.

4. The recording device according to claim 1, wherein
the interface unit conforms to an NVMe standard, and
the command indicating the optimal performance operation mode is a set features command of the NVMe standard.

5. The recording device according to claim 1, wherein
the interface unit conforms to an SD memory card standard and an NVMe standard, and
the optimal performance operation mode is valid only when data is recorded in accordance with the protocol of the NVMe standard.

6. A non-volatile storage device that records data at a guaranteed minimum recording speed using a recording device, the non-volatile storage device comprising
an interface unit physically connected to the recording device and having a transfer speed higher than the minimum recording speed, wherein
the interface unit
is configured to receive, from the recording device, a data write command instructing data recording, and a control command including a command instructing speed guarantee recording and a command instructing a shift to an optimal performance operation mode, and
receives the data write command instructing data recording after receiving the command instructing the speed guarantee recording and the command instructing the shift to the optimal performance operation mode.

7. The non-volatile storage device according to claim 6, wherein a recording speed of the optimal performance operation mode is faster than the minimum recording speed and slower than a maximum transfer speed by the interface unit.

8. The non-volatile storage device according to claim 6, wherein
the interface unit conforms to an NVMe standard, and
the command instructing the optimal performance operation mode is a data set management command of the NVMe standard.

9. The non-volatile storage device according to claim 6, wherein
the interface unit conforms to an NVMe standard, and
the command instructing the optimal performance operation mode is a set features command of the NVMe standard.

10. The non-volatile storage device according to claim 6, wherein
the interface unit conforms to an SD memory card standard and an NVMe standard, and
the optimal performance operation mode is valid only when data is recorded in accordance with the protocol of the NVMe standard.

11. A recording method executed in a recording device that records data in a non-volatile storage device at a minimum recording speed via an interface unit having a transfer speed higher than a guaranteed minimum recording speed, the recording method comprising:
transmitting a command instructing speed guarantee recording and a command instructing a shift to an optimal performance operation mode; and
transmitting a data write command instructing the data recording to the non-volatile storage device.

12. The recording method according to claim 11, wherein a recording speed of the optimal performance operation mode is faster than the minimum recording speed and slower than a maximum transfer speed by the interface unit.

13. The recording method according to claim 11, wherein
the recording device conforms to an NVMe standard, and
the command instructing the optimal performance operation mode is a data set management command of the NVMe standard.

14. The recording method according to claim 11, wherein
the recording device conforms to an NVMe standard, and
the command instructing the optimal performance operation mode is a set features command of the NVMe standard.

15. The recording method according to claim 11, wherein
the recording device conforms to an NVMe standard, and
the optimal performance operation mode is valid only when data is recorded in accordance with the protocol of the NVMe standard.
